(19) United States
(12) Patent Application Publication
(10) Pub. No.: US 2017/0047128 A1
(43) Pub. Date: Feb. 16, 2017

(54) SHIFT REGISTER CIRCUIT

(71) Applicant: Shenzhen China Star Optoelectronics Technology Co., Ltd., Shenzhen, Guangdong (CN)

(72) Inventor: Chao DAI, Shenzhen, Guangdong (CN)

(73) Assignee: Shenzhen China Star Optoelectronics Technology Co., Ltd., Shenzhen, Guangdong (CN)

(21) Appl. No.: 14/654,420

(22) PCT Filed: Apr. 22, 2015
(86) PCT No.: PCT/CN2015/077167

§ 371 Date: Jun. 19, 2015

(30) Foreign Application Priority Data
Mar. 31, 2015 (CN) 201510147982.1

(51) Int. Cl. G11C 19/28

(52) U.S. Cl. CPC G11C 19/28

(57) ABSTRACT

Disclosed is a shift register circuit, having shift register sub circuits, and a shift register sub circuit of a Nth stage has a control signal input end, a clock signal output control circuit, a buffer and a signal output end. The control signal input end of the Nth stage receives an output signal of a shift register sub circuit of a N−1 th stage. The first transistor transmits the output signal of the shift register sub circuit of the N−1th stage to the node under control of the first clock signal. The second transistor transmits the second clock signal to the source of the second transistor under control of the outputted signal of the shift register sub circuit of the N−1th stage. The buffer buffers the outputted signal with a predetermined period to obtain and outputs an output signal of the shift register sub circuit of the Nth stage.

### CROSS REFERENCE

This application claims the priority of Chinese Patent Application No. 201510147982.1, entitled “Shift register circuit”, filed on Mar. 31, 2015, the disclosure of which is incorporated herein by reference in its entirety.

### FIELD OF THE INVENTION

The present invention relates to a display field, and more particularly to a shift register circuit.

### BACKGROUND OF THE INVENTION

Gate Driver on Array (GOA) is a high level design in the liquid crystal display technology. The basic concept of GOA is integrating the Gate Driver of the liquid crystal display panel on the glass substrate to form the scan drive to the liquid crystal display panel. As designing the Gate Driver, the shift register circuit is commonly utilized. The design of the present shift register circuit generally utilizes CMOS elements to reduce the power consumption of the shift register circuit and to raise the stability of the shift register circuit. However, for the single type transistor (such as N-type transistor), the shift register circuit design of single type transistor has not been proposed yet.

### SUMMARY OF THE INVENTION

The present invention provides a shift register circuit, wherein the shift register circuit comprises shift register sub circuits of M stages, and a shift register sub circuit of a Nth stage comprises a control signal input end of the Nth stage, a clock signal output control circuit, a buffer and a signal output end of the Nth stage which are electrically coupled in sequence, and the control signal input end of the Nth stage is employed to receive an output signal of a shift register sub circuit of a N−1th stage, and the clock signal output control circuit comprises a first transistor and a second transistor, and the first transistor comprises a first gate, a first source and a first drain, and the second transistor comprises a second gate, a second source and a second rain, and the first gate receives a first clock signal, and the first source is coupled to the control signal input end of the Nth stage to receive the output signal of the shift register sub circuit of the N−1th stage, and the first drain is electrically coupled to the second gate via a node, and the first transistor transmits the output signal of the shift register sub circuit of the N−1th stage to the node under control of the first clock signal, and the second drain receives a second clock signal, and the second transistor transmits the second clock signal to the second source under control of the output signal of the shift register sub circuit of the N−1th stage, and the second source is employed to be an output end of the clock signal output control circuit to be electrically coupled to the buffer, and the buffer is employed to buffer an signal outputted by the second source with a predetermined period to obtain an output signal of the shift register sub circuit of the Nth stage and outputs the same via the signal output end of the Nth stage, wherein both the first clock signal and the second clock signal are square wave signals, and a high voltage level of the first clock signal and a high voltage level of the second clock signal do not coincide, and a duty ratio of the first clock signal is smaller than 1, and a duty ratio of the second clock signal is smaller than 1, and M and N are natural numbers, and M is greater than or equal to N.

The shift register circuit further comprises a shift register sub circuit of a N+1th stage, and the shift register sub circuit of the N+1th stage comprises the same elements of the shift register sub circuit of the Nth stage, and a first gate of a first transistor in the shift register sub circuit of the N+1th stage receives the second clock signal, and a second drain of a second transistor in the shift register sub circuit of the N+1th stage receives the first clock signal.

Each shift register circuit further comprises a third transistor, and the third transistor comprises a third gate, a third source and a third drain, wherein the third gate receives the same clock signal of the first gate of the first transistor, and the third source is electrically coupled to the second drain, and the third drain is electrically coupled to the second source.

The shift register circuit further comprises a shift register sub circuit of a N+1th stage and a shift register sub circuit of a N+2th stage, and the shift register sub circuit of the N+1th stage and the shift register sub circuit of the N+2th stage comprise the same elements of the shift register sub circuit of the Nth stage, and a first gate of a first transistor in the shift register sub circuit of the N+1th stage receives the second clock signal, and a second drain of a second transistor in the shift register sub circuit of the N+1th stage receives a third clock signal, and the third gate of the third transistor of the shift register sub circuit of the N+1th stage receives the same clock signal of the first gate of the first transistor of the shift register sub circuit of the N+1th stage; a first gate of a first transistor in the shift register sub circuit of the N+2th stage receives the third clock signal, and a second drain of a second transistor of the shift register sub circuit of the N+2th stage receives the first clock signal, and the third gate of the third transistor of the shift register sub circuit of the N+2th stage receives the same clock signal of the first gate of the first transistor of the shift register sub circuit of the N+1th stage, wherein the third clock signal is a square wave signal, and a high voltage level of the third clock signal and the high voltage level of the first clock signal do not coincide, and the high voltage level of the third clock signal and the high voltage level of the second clock signal do not coincide, and the duty ratio of the third clock signal is smaller than 1.

The shift register circuit further comprises a shift register sub circuit of a N+1th stage, a shift register sub circuit of a N+2th stage and a shift register sub circuit of a N+3th stage, and the shift register sub circuit of the N+1th stage, the shift register sub circuit of the N+2th stage and the shift register sub circuit of the N+3th stage comprise the same elements of the shift register sub circuit of the Nth stage, and a first gate of a first transistor in the shift register sub circuit of the N+1th stage receives the second clock signal, and a second drain of a second transistor in the shift register sub circuit of the N+1th stage receives a third clock signal, and the third gate of the third transistor of the shift register sub circuit of the N+1th stage receives the same clock signal of the first gate of the first transistor of the shift register sub circuit of the N+1th stage; a first gate of a first transistor in the shift register sub circuit of the N+2th stage receives the third clock signal, and a second drain of a second transistor of the shift register sub circuit of the N+2th stage receives a fourth clock signal, and the third gate of the third transistor of the shift register sub circuit of the N+2th stage receives the same clock signal of the first gate of the first transistor of the shift register sub circuit of the N+1th stage; a first gate of a first transistor in the shift register sub circuit of the N+3th stage receives the fourth clock signal, and a second drain of a second transistor in the shift register sub circuit of the N+3th stage receives the first clock signal, and the third gate of the third transistor in the shift register sub circuit of the N+3th stage receives the same clock signal of the first gate of a first transistor of the shift register sub circuit of the N+3th stage, wherein the third clock signal and the fourth clock signal are square wave signals, and a high voltage level of the third clock signal and a high voltage level of the fourth clock signal do not coincide, and the high voltage level of the third clock signal, the high voltage level of the fourth clock signal and the high voltage level of the first clock signal, the high voltage level of the second clock signal do not coincide, and the duty ratio of the third clock signal is smaller than 1, and the duty ratio of the fourth clock signal is smaller than 1.

All the duty ratio of the first clock signal, the duty ratio of the second clock signal, the duty ratio of the third clock signal and the duty ratio of the fourth clock signal are 1/3.

As N is equal to one, the control signal input end of the first stage receives a shift register activation signal, wherein the shift register activation signal is employed to control an activation of the first transistor of the shift register sub circuit of the first stage, wherein the shift register activation signal is a high voltage level signal, of which a lasting period is a first predetermined period.

The buffer comprises a first inverter and a second inverter sequentially coupled in series, and an input end of the first inverter is coupled to the second source, and an output end of the second inverter is coupled to the signal output end of the Nth stage.

The buffer further comprises a third inverter, and an input end of the third inverter is electrically coupled to a node between the first inverter and the second inverter, and an output end of the third inverter is electrically coupled to a stage transfer node, and a signal outputted from the output end of the third inverter is transmitted to the shift register sub circuit of the next stage via the stage transfer node.

The first inverter comprises a first main transistor (T51), a second main transistor (T52), a third main transistor (T53), a fourth main transistor (T54), a first auxiliary transistor (T61), a second auxiliary transistor (T62), a third auxiliary transistor (T63) and a fourth auxiliary transistor (T64); the first main transistor (T51), the second main transistor (T52), the third main transistor (T53), the fourth main transistor (T54), the first auxiliary transistor (T61), the second auxiliary transistor (T62), the third auxiliary transistor (T63) and the fourth auxiliary transistor (T64) respectively comprises a gate, a source and a drain, and both the gate and the source of the first main transistor (T51) are coupled to a high voltage level signal end for receiving a high voltage level signal, and the drain of the first main transistor (T51) is electrically coupled to the gate of the second main transistor (T52), and the source of the second main transistor (T52) is electrically coupled to the high voltage level signal end, and the drain of the second main transistor (T52) is electrically coupled to an output end of the first inverter, and the gate of the third main transistor (T53) is electrically coupled to the input end of the first inverter, and the source of the third main transistor (T53) is electrically coupled to the drain of the first main transistor (T51), and the drain of the third main transistor (T53) is electrically coupled to the drain of the fourth main transistor (T54), and the gate of the fourth main transistor (T54) is electrically coupled to the input end of the first inverter, and the source of the fourth main transistor (T54) is electrically coupled to the output end of the first inverter, and both the gate and the source of the first auxiliary transistor (T61) are coupled to the high voltage level signal end for receiving a high voltage level signal, and the drain of the first auxiliary transistor (T61) is electrically coupled to the gate of the second auxiliary transistor (T62), and the source of the second auxiliary transistor (T62) is electrically coupled to the high voltage level signal end, and the drain of the second auxiliary transistor (T62) is electrically coupled to the drain of the fourth main transistor (T54), and the gate of the third auxiliary transistor (T63) is electrically coupled to the input end of the first inverter, and the source of the third auxiliary transistor (T63) is electrically coupled to the drain of the first auxiliary transistor (T61), and the drain of the third auxiliary transistor (T63) is electrically coupled to a low voltage level signal end (VSS), and the gate of the fourth auxiliary transistor (T64) is electrically coupled to the input end of the first inverter, and the source of the fourth auxiliary transistor (T64) is electrically coupled to the drain of the second auxiliary transistor (T62), and the drain of the fourth auxiliary transistor (T64) is electrically coupled to the low voltage level signal end.

The second inverter comprises a first main transistor (T71), a second main transistor (T72), a third main transistor (T73), a fourth main transistor (T74), a first auxiliary transistor (T81), a second auxiliary transistor (T82), a third auxiliary transistor (T83) and a fourth auxiliary transistor (T84); the first main transistor (T71), the second main transistor (T72), the third main transistor (T73), the fourth main transistor (T74), the first auxiliary transistor (T81), the second auxiliary transistor (T82), the third auxiliary transistor (T83) and the fourth auxiliary transistor (T84) respectively comprises a gate, a source and a drain, and both the gate and the source of the first main transistor (T71) are coupled to the high voltage level signal end for receiving a high voltage level signal, and the drain of the first main transistor (T71) is electrically coupled to the gate of the second main transistor (T72), and the source of the second main transistor (T72) is electrically coupled to the high voltage level signal end, and the drain of the second main transistor (T72) is electrically coupled to an output end 132 (N) of the second inverter, and the gate of the third main transistor (T73) is electrically coupled to the output end of the first inverter, and the source of the third main transistor (T73) is electrically coupled to the drain of the first main transistor (T71), and the drain of the third main transistor (T73) is electrically coupled to the drain of the fourth main transistor (T74), and the gate of the fourth main transistor (T74) is electrically coupled to the input end of the first inverter, and the source of the fourth main transistor (T74) is electrically coupled to the output end of the second inverter, and the drain of the fourth main transistor (T74) is electrically coupled to source of the fourth auxiliary transistor (T84), and the gate and the source of the first auxiliary transistor (T81) are coupled to the high voltage level signal end for receiving a high voltage level signal, and the drain of the first auxiliary transistor (T81) is electrically coupled to the gate of the second auxiliary transistor (T82), and the source of the second auxiliary transistor (T82) is electrically coupled to the high voltage level signal end, and the drain of the second auxiliary transistor (T82) is electrically coupled to the source of the fourth main transistor (T84), and the gate of the third auxiliary transistor (T83) is electrically coupled to the output end of the first inverter, and the source of the third auxiliary transistor (T83) is electrically coupled to the drain of the first auxiliary transistor (T81), and the drain of the third auxiliary transistor (T83) is electrically coupled to the low voltage level signal end, and the gate of the fourth auxiliary transistor (T84) is electrically coupled to the output end of the first inverter, and the source of the fourth auxiliary transistor (T84) is electrically coupled to the drain of the second auxiliary transistor (T82), and the drain of the fourth auxiliary transistor (T84) is electrically coupled to the low voltage level signal end.

The third inverter comprises a first main transistor (T31), a second main transistor (T32), a third main transistor (T33), a fourth main transistor (T34), a first auxiliary transistor (T41), a second auxiliary transistor (T42), a third auxiliary transistor (T43) and a fourth auxiliary transistor (T44); the first main transistor (T31), the second main transistor (T32), the third main transistor (T33), the fourth main transistor (T34), the first auxiliary transistor (T41), the second auxiliary transistor (T42), the third auxiliary transistor (T43) and the fourth auxiliary transistor (T44) respectively comprises a gate, a source and a drain, and both the gate and the source of the first main transistor (T31) are coupled to a high voltage level signal end for receiving a high voltage level signal, and the drain of the first main transistor (T31) is electrically coupled to the gate of the second main transistor (T32), and the source of the second main transistor (T32) is electrically coupled to the high voltage level signal end, and the drain of the second main transistor (T32) is electrically coupled to the stage transfer node, and the gate of the third main transistor (T33) is electrically coupled to the output end of the first inverter, and the source of the third main transistor (T33) is electrically coupled to the drain of the first main transistor (T31), and the drain of the third main transistor (T33) is electrically coupled to the drain of the fourth main transistor (T34), and the gate of the fourth main transistor (T34) is electrically coupled to the output end of the first inverter, and the source of the fourth main transistor (T34) is electrically coupled to the stage transfer node, and the drain of the fourth main transistor (T34) is electrically coupled to the source of the fourth auxiliary transistor (T44), and both the gate and the source of the first auxiliary transistor (T41) are coupled to the high voltage level signal end for receiving a high voltage level signal, and the drain of the first auxiliary transistor (T41) is electrically coupled to the gate of the second auxiliary transistor (T42), and the source of the second auxiliary transistor (T42) is electrically coupled to the high voltage level signal end, and the drain of the second auxiliary transistor (T42) is electrically coupled to the source of the fourth auxiliary transistor (T44), and the gate of the third auxiliary transistor (T43) is electrically coupled to the output end of the first inverter, and the source of the third auxiliary transistor (T43) is electrically coupled to the drain of the first auxiliary transistor (T41), and the drain of the third auxiliary transistor (T43) is electrically coupled to a low voltage level signal end, and the gate of the fourth auxiliary transistor (T44) is electrically coupled to the output end of the first inverter, and the source of the fourth auxiliary transistor (T44) is electrically coupled to the drain of the second auxiliary transistor (T42), and the drain of the fourth auxiliary transistor (T44) is electrically coupled to the low voltage level signal end.

The first inverter comprises a second main transistor (T52), a fourth main transistor (T54), a first auxiliary transistor (T61), a second auxiliary transistor (T62), a third auxiliary transistor (T63) and a fourth auxiliary transistor (T64); the second main transistor (T52), the fourth main transistor (T54), the first auxiliary transistor (T61), the second auxiliary transistor (T62), the third auxiliary transistor (T63) and the fourth auxiliary transistor (T64) respectively comprises a gate, a source and a drain, and the gate of the second main transistor (T52) is electrically coupled to the drain of the first auxiliary transistor (T61), and the source of the second main transistor (T52) is electrically coupled to a high voltage level signal end for receiving a high voltage level signal, and the drain of the second main transistor (T52) is electrically coupled to an output end of the first inverter, and the gate of the fourth main transistor (T54) is electrically coupled to the input end of the first inverter, and the source of the fourth main transistor (T54) is electrically coupled to the output end of the first inverter, and the drain of the fourth main transistor (T54) is electrically coupled to the drain of the second auxiliary transistor (T62), and both the gate and the source of the first auxiliary transistor (T61) are electrically coupled to the high voltage level signal end for receiving a high voltage level signal, and the drain of the first auxiliary transistor (T61) is electrically coupled to the gate of the second auxiliary transistor (T62), and the source of the second auxiliary transistor (T62) is electrically coupled to the high voltage level signal end for receiving a high voltage level signal, and the drain of the second auxiliary transistor (T62) is electrically coupled to the source of the fourth auxiliary transistor (T64). the gate of the third auxiliary transistor (T63) is electrically coupled to the input end of the first inverter, and the source of the third auxiliary transistor (T63) is electrically coupled to the drain of the first auxiliary transistor (T61), and the drain of the third auxiliary transistor (T63) is electrically coupled to a low voltage level signal end (VSS1), and the gate of the fourth auxiliary transistor (T64) is electrically coupled to the input end of the first inverter, and the source of the fourth auxiliary transistor (T64) is electrically coupled to the drain of the second auxiliary transistor (T62), and the drain of the fourth auxiliary transistor (T64) is electrically coupled to the low voltage level signal end (VSS1).

The second inverter comprises a second main transistor (T72), a fourth main transistor (T74), a first auxiliary transistor (T81), a second auxiliary transistor (T82), a third auxiliary transistor (T83) and a fourth auxiliary transistor (T84); the second main transistor (T72), the fourth main transistor (T74), the first auxiliary transistor (T81), the second auxiliary transistor (T82), the third auxiliary transistor (T83) and the fourth auxiliary transistor (T84) respectively comprises a gate, a source and a drain, and the gate of the second main transistor (T72) is electrically coupled to the drain of the first auxiliary transistor (T81), and the source of the second main transistor (T72) is electrically coupled to the high voltage level signal end, and the drain of the second main transistor (T72) is electrically coupled to an output end of the second inverter, and the gate of the fourth main transistor (T74) is electrically coupled to the output end of the first inverter, and the source of the fourth main transistor (T74) is electrically coupled to the output end of the second inverter, and the drain of the fourth main transistor (T74) is electrically coupled to drain of the second auxiliary transistor (T82), and the gate and the source of the first auxiliary transistor (T81) are coupled to the high voltage level signal end, and the drain of the first auxiliary transistor (T81) is electrically coupled to the gate of the second auxiliary transistor (T82), and the source of the second auxiliary transistor (T82) is electrically coupled to the high voltage level signal end, and the drain of the second auxiliary transistor (T82) is electrically coupled to the source of the fourth main transistor (T84), and the gate of the third auxiliary transistor (T83) is electrically coupled to the output end of the first inverter, and the source of the third auxiliary transistor (T83) is electrically coupled to the drain of the first auxiliary transistor (T81), and the drain of the third auxiliary transistor (T83) is electrically coupled to the low voltage level signal end, and the gate of the fourth auxiliary transistor (T84) is electrically coupled to the output end of the first inverter, and the source of the fourth auxiliary transistor (T84) is electrically coupled to the drain of the second auxiliary transistor (T82), and the drain of the fourth auxiliary transistor (T84) is electrically coupled to the low voltage level signal end.

The third inverter comprises a second main transistor (T32), a fourth main transistor (T34), a first auxiliary transistor (T41), a second auxiliary transistor (T42), a third auxiliary transistor (T43) and a fourth auxiliary transistor (T44); the second main transistor (T32), the fourth main transistor (T34), the first auxiliary transistor (T41), the second auxiliary transistor (T42), the third auxiliary transistor (T43) and the fourth auxiliary transistor (T44) respectively comprises a gate, a source and a drain, and the gate of the second main transistor (T32) is electrically coupled to the drain of the first auxiliary transistor (T41), and the source of the second main transistor (T32) is electrically coupled to the high voltage level signal end, and the drain of the second main transistor (T32) is electrically coupled to the stage transfer node, and the gate of the fourth main transistor (T34) is electrically coupled to the output end of the first inverter, and the source of the fourth main transistor (T34) is electrically coupled to the stage transfer node, and the drain of the fourth main transistor (T34) is electrically coupled to the source of the fourth auxiliary transistor (T44), and both the gate and the source of the first auxiliary transistor (T41) are electrically coupled to the high voltage level signal end, and the drain of the first auxiliary transistor (T41) is electrically coupled to the gate of the second auxiliary transistor (T42), and the source of the second auxiliary transistor (T42) is electrically coupled to the high voltage level signal end, and the drain of the second auxiliary transistor (T42) is electrically coupled to the source of the fourth auxiliary transistor (T44), and the gate of the third auxiliary transistor (T43) is electrically coupled to the output end of the first inverter, and the source of the third auxiliary transistor (T43) is electrically coupled to the drain of the first auxiliary transistor (T41), and the drain of the third auxiliary transistor (T43) is electrically coupled to a low voltage level signal end, and the gate of the fourth auxiliary transistor (T44) is electrically coupled to the output end of the first inverter, and the source of the fourth auxiliary transistor (T44) is electrically coupled to the drain of the second auxiliary transistor (T42), and the drain of the fourth auxiliary transistor (T44) is electrically coupled to the low voltage level signal end.

The third inverter comprises a second main transistor (T32), a fourth main transistor (T34), a first auxiliary transistor (T41), a second auxiliary transistor (T42), a third auxiliary transistor (T43) and a fourth auxiliary transistor (T44); the second main transistor (T32), the fourth main transistor (T34), the first auxiliary transistor (T41), the second auxiliary transistor (T42), the third auxiliary transistor (T43) and the fourth auxiliary transistor (T44) respectively comprises a gate, a source and a drain, and the gate of the second main transistor (T32) is electrically coupled to the drain of the first auxiliary transistor (T41), and the source of the second main transistor (T32) is electrically coupled to the high voltage level signal end, and the drain of the second main transistor (T32) is electrically coupled to the stage transfer node, and the gate of the fourth main transistor (T34) is electrically coupled to the output end of the first inverter, and the source of the fourth main transistor (T34) is electrically coupled to the stage transfer node, and the drain of the fourth main transistor (T34) is electrically coupled to the source of the fourth auxiliary transistor (T44), and both the gate and the source of the first auxiliary transistor (T41) are electrically coupled to the high voltage level signal end, and the drain of the first auxiliary transistor (T41) is electrically coupled to the gate of the second auxiliary transistor (T42), and the source of the second auxiliary transistor (T42) is electrically coupled to the high voltage level signal end, and the drain of the second auxiliary transistor (T42) is electrically coupled to the source of the fourth auxiliary transistor (T44), and the gate of the third auxiliary transistor (T43) is electrically coupled to the output end of the first inverter, and the source of the third auxiliary transistor (T43) is electrically coupled to the drain of the first auxiliary transistor (T41), and the drain of the third auxiliary transistor (T43) is electrically coupled to a low voltage level signal end, and the gate of the fourth auxiliary transistor (T44) is electrically coupled to the output end of the first inverter, and the source of the fourth auxiliary transistor (T44) is electrically coupled to the drain of the second auxiliary transistor (T42), and the drain of the fourth auxiliary transistor (T44) is electrically coupled to the low voltage level signal end.

The third inverter comprises a second main transistor (T32), a fourth main transistor (T34), a second auxiliary transistor (T42) and a fourth auxiliary transistor (T44); the second main transistor (T32), the fourth main transistor (T34), the second auxiliary transistor (T42) and the fourth auxiliary transistor (T44) respectively comprises a gate, a source and a drain, and the gate of the second main transistor (T32) is electrically coupled to the gate of the second main transistor (T72) in the second inverter, and the source of the second main transistor (T32) is electrically coupled to the high voltage level signal end, and the drain of the second main transistor (T32) is electrically coupled to the stage transfer node, and the gate of the fourth main transistor (T34) is electrically coupled to the output end of the first inverter, and the source of the fourth main transistor (T34) is electrically coupled to the stage transfer node, and the drain of the fourth main transistor (T34) is electrically coupled to the drain of the second auxiliary transistor (T42), the gate of the second auxiliary transistor (T42) is electrically coupled to the gate of the second main transistor (T32), and the source of the second auxiliary transistor (T42) is electrically coupled to the high voltage level signal end, and the drain of the second auxiliary transistor (T42) is electrically coupled to the source of the fourth auxiliary transistor (T44), and the gate of the fourth auxiliary transistor (T44) is electrically coupled to the output end of the first inverter, and the drain of the fourth auxiliary transistor (T44) is electrically coupled to the low voltage level signal end.

### BRIEF DESCRIPTION OF THE DRAWINGS

In order to more clearly illustrate the embodiments of the present invention or prior art, the following figures will be described in the embodiments are briefly introduced. It is obvious that the drawings are merely some embodiments of the present invention, those of ordinary skill in this field can obtain other figures according to these figures without paying the premise.

FIG. 1 is a structural diagram of a shift register circuit according to the first preferred embodiment of the present invention.

FIG. 2 is a structural diagram of a shift register sub circuit as N=1 in a shift register circuit according to the first preferred embodiment of the present invention.

FIG. 3 is a time sequence diagram of respective signals in the first preferred embodiment of the present invention.

FIG. 4 is a structural diagram of a shift register circuit according to the second preferred embodiment of the present invention.

FIG. 5 is a structural diagram of a shift register sub circuit as N=1 in a shift register circuit according to the second preferred embodiment of the present invention.

FIG. 6 is a structural diagram of specific circuit of a shift register sub circuit of a Nth stage in a shift register circuit according to the third preferred embodiment of the present invention.

FIG. 7 is a structural diagram of a shift register circuit according to the fourth preferred embodiment of the present invention.

FIG. 8 is a time sequence diagram of respective signals in the fourth preferred embodiment of the present invention.

FIG. 9 is a structural diagram of a shift register circuit according to the fifth preferred embodiment of the present invention.

FIG. 10 is a time sequence diagram of respective signals in the fifth preferred embodiment of the present invention.

FIG. 11 is a structural diagram of a shift register sub circuit of a Nth stage in a shift register circuit according to the sixth preferred embodiment of the present invention.

FIG. 12 is a structural diagram of specific circuit of a shift register sub circuit of a Nth stage in a shift register circuit according to the sixth preferred embodiment of the present invention.

FIG. 13 is a structural diagram of specific circuit of a shift register sub circuit of a Nth stage in a shift register circuit according to the seventh preferred embodiment of the present invention.

FIG. 14 is a structural diagram of specific circuit of a shift register sub circuit of a Nth stage in a shift register circuit according to the eighth preferred embodiment of the present invention.

### DETAILED DESCRIPTION OF PREFERRED EMBODIMENTS

Embodiments of the present invention are described in detail with the technical matters, structural features, achieved objects, and effects with reference to the accompanying drawings as follows. It is clear that the described embodiments are part of embodiments of the present invention, but not all embodiments. Based on the embodiments of the present invention, all other embodiments to those of ordinary skill in the premise of no creative efforts obtained, should be considered within the scope of protection of the present invention.

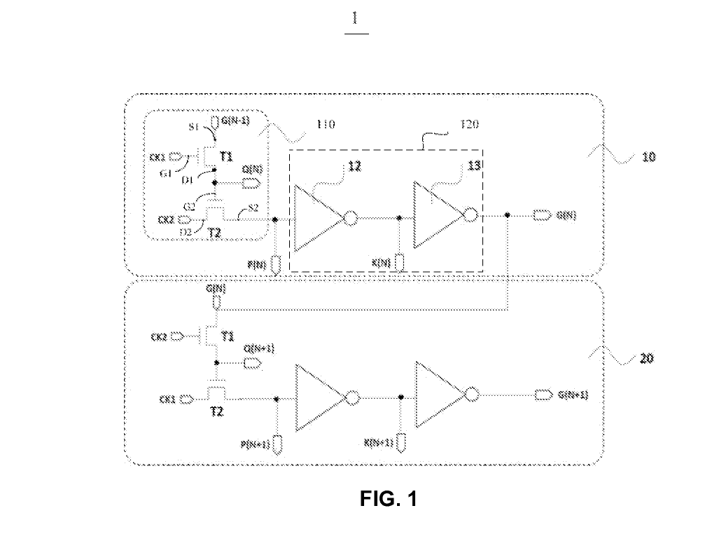

Please refer to FIG. 1. FIG. 1 is a structural diagram of a shift register circuit according to the first preferred embodiment of the present invention. The shift register circuit 1 comprises shift register sub circuits of M stages, and structures of the shift register sub circuits are the same. That is to say, the shift register sub circuits comprise the same elements, and the connection relationship of the elements in the shift register sub circuits are the same. Here, a shift register sub circuit of a Nth stage 10 and a shift register sub circuit of a N+1th stage 20 are illustrated for introduction of the shift register circuit 1.The shift register sub circuit of the Nth stage 10 comprises a control signal input end G(N−1) of the Nth stage, a clock signal output control circuit 110, a buffer 120 and a signal output end G(N) of the Nth stage. The control signal input end G(N−1) of the Nth stage is employed to receive an output signal of a shift register sub circuit of a N−1th stage. The clock signal output control circuit 110 comprises a first transistor T1 and a second transistor T2, and the first transistor T1 comprises a first gate G1, a first source S1 and a first drain D1, and the second transistor T2 comprises a second gate G2, a second source S2 and a second rain D2.The first gate G1 receives a first clock signal CK1, and the first source S1 is coupled to the control signal input end of the Nth stage to receive the output signal of the shift register sub circuit of the N−1th stage, and the first drain D1 is electrically coupled to the second gate G2 via a node Q(N).The first transistor T1 transmits the output signal of the shift register sub circuit of the N−1th stage to the node Q(N) under control of the first clock signal CK1.The second drain D2 receives a second clock signal CK2, and the second transistor T2 transmits the second clock signal CK2 to the second source S2 under control of the output signal of the shift register sub circuit of the N−1th stage. The second source S2 is employed to be an output end of the clock signal output control circuit 11 to be electrically coupled to the buffer 120. The buffer 120 is employed to buffer an signal outputted by the second source S2 with a predetermined period to obtain an output signal of the shift register sub circuit of the Nth stage and outputs the same via the signal output end G(N) of the Nth stage. Both the first clock signal CK1 and the second clock signal Ck2 are square wave signals, and a high voltage level of the first clock signal CK1 and a high voltage level of the second clock signal CK2 do not coincide, and M and N are natural numbers, and M is greater than or equal to N.

The buffer 120 comprises a first inverter 12 and a second inverter 13 sequentially coupled in series, and an input end of the first inverter 12 is coupled to the second source S2 to receive the output signal of the clock signal output control circuit 110. The first inverter 12 is employed to invert the output signal of the clock signal output control circuit 110. The second inverter 13 is employed to invert the output signal from the first inverter 12. Therefore, the waveform of the signal outputted from the output end of the second inverter 13 coincides with the waveform of the output signal of the clock signal output control circuit 110 but the signal outputted by the second inverter 13 delays the predetermined period than the output signal of the clock signal output control circuit 110 after passing through the first inverter 12 and the second inverter 13. An output end of the second inverter 13 is coupled to the signal output end G(N) of the Nth stage to output the output signal of the shift register sub circuit of the Nth stage via the signal output end G(N) of the Nth stage. The buffer 120 comprising two inverters, the first inverter 12 and the second inverter 13 can effectively prevent the influence of the clock signals of the clock output control circuit 110 to the output signal from the output end of the shift register sub circuit of the Nth stage.

The shift register circuit 1 further comprises a shift register sub circuit 20 of a N+1th stage, and the shift register sub circuit 20 of the N+1th stage comprises the same elements of the shift register sub circuit 10 of the Nth stage. What is different is that a first gate of a first transistor T1 in the shift register sub circuit 20 of the N+1th stage receives the second clock signal CK2, and a second drain of a second transistor T2 in the shift register sub circuit 20 of the N+1th stage receives the first clock signal CK1.

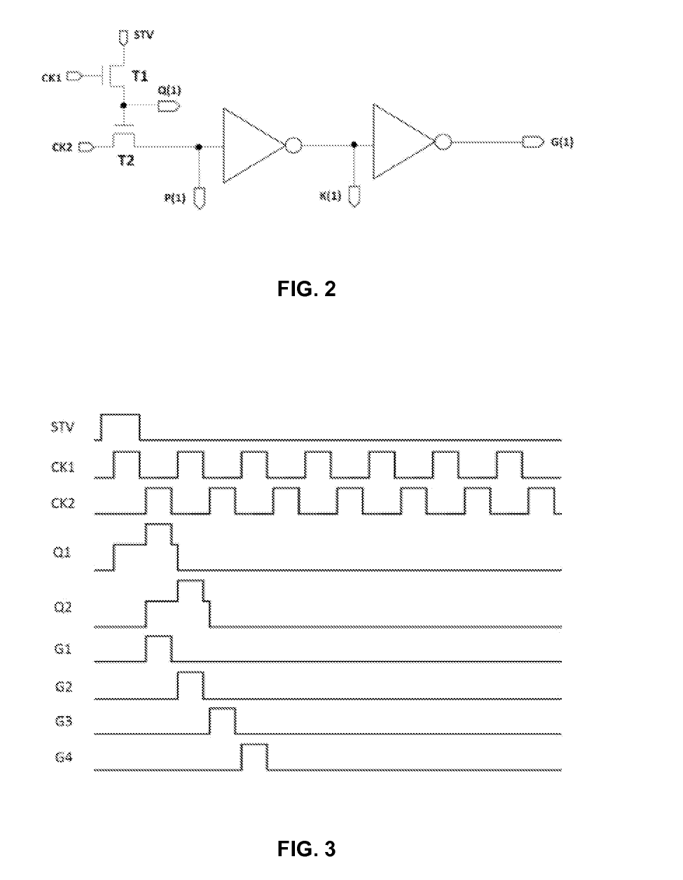

Please also refer to FIG. 2. FIG. 2 is a structural diagram of a shift register sub circuit as N=1 in a shift register circuit according to the first preferred embodiment of the present invention. As N=1, FIG. 2 is a structural diagram of a shift register sub circuit of the first stage of the present invention. Comparing the shift register sub circuits 10 of the Nth stage in FIG. 2 and FIG. 1, the structure of the shift register sub circuit of the first stage is the same as the structure of the shift register sub circuit 10 of the Nth stage shown in FIG. 1. The difference is that the control signal input end of the first stage (here is the source of the first transistor T1 in the shift register sub circuit of the first stage) in the shift register sub circuit of the first stage receives a shift register activation signal STV, wherein the shift register activation signal STV is employed to control an activation of the first transistor T1 of the shift register sub circuit of the first stage. The shift register activation signal STV is a high voltage level signal, of which a lasting period is a first predetermined period. That is, the shift register activation signal STV is a low voltage level signal in the beginning, and becomes the high voltage level signal, of which the lasting period is the first predetermined period, and then becomes the low voltage level signal.

Please also refer to FIG. 3. FIG. 3 is a time sequence diagram of respective signals in the first preferred embodiment of the present invention. The shift register activation signal is STV. The first clock signal is CK1. The second clock signal is CK2. The node of the shift register sub circuit of the first stage is Q1. The node of the shift register sub circuit of the second stage is Q2. The output signal of the shift register sub circuit of the first stage is G1. The output signal of the shift register sub circuit of the second stage is G2. The output signal of the shift register sub circuit of the third stage is G3. The output signal of the shift register sub circuit of the fourth stage is G4. As the first waveform diagram of the respective signals in FIG. 3, the shift register activation signal STV is a high voltage level signal, of which a lasting period is a first predetermined period. The high voltage level signal lasts with the first predetermined period, and then, the shift register activation signal STV becomes a low voltage level signal. The first clock signal CK1 is a square wave signal, and the second clock signal CK2 is a square wave signal, too. The start point of the high voltage level of the shift register activation signal SW is earlier than the start point of the high voltage level of the first clock signal CK1. The finish point of the high voltage level of the shift register activation signal STV is the same as the finish point of the high voltage level of the first clock signal CK1. A high voltage level of the second clock signal CK2 and a high voltage level of the first clock signal CK1 do not coincide. A duty ratio of the first clock signal CK1 is smaller than 1, and a duty ratio of the second clock signal CK2 is smaller than 1, too. In this embodiment, the duty ratio of the first clock signal CK1 is 40/60, and the duty ratio of the second clock signal CK2 is 40/60, too. The waveform of the first clock signal CK1 and the waveform of the second clock signal CK2 of this embodiment are the waveforms at the node Q(N) appearing to be protuberant. In FIG. 3, only the waveforms at the node Q(N) as N=1, and N=2 are shown, and as shown in FIG. 3, the waveform at the Q(2) delays than the waveform at the Q(1). The output signal of the shift register sub circuit of the first stage G1 is a high voltage level signal, of which a lasting period is a second predetermined period. In this embodiment, the second predetermined period is equal to a last period of a high voltage level of the second clock signal CK2 in a cycle time. The waveforms of the output signal of the shift register sub circuit of the first stage G1, the output signal of the shift register sub circuit of the second stage G2, the output signal of the shift register sub circuit of the third stage G3 and the output signal of the shift register sub circuit of the fourth stage G4 are basically identical. However, the output signal of the shift register sub circuit of the second stage G2 delays a period of time than the output signal of the shift register sub circuit of the first stage G1. For convenience, the period of time, of which the output signal of the shift register sub circuit of the second stage G2 delays than the output signal of the shift register sub circuit of the first stage G1 is named to be a first predetermined delay period. The output signal of the shift register sub circuit of the third stage G3 delays the first predetermined delay period than the output signal of the shift register sub circuit of the second stage G2. The output signal of the shift register sub circuit of the fourth stage G4 delays the first predetermined delay period than the output signal of the shift register sub circuit of the third stage G3. Namely, the output signal of the shift register sub circuit of the Nth stage delays the first predetermined delay period than the output signal of the shift register sub circuit of the N+1th stage. In one embodiment, a predetermined delay period is equal to a second predetermined period, a lasting period of a high voltage level of the shift register sub circuit.

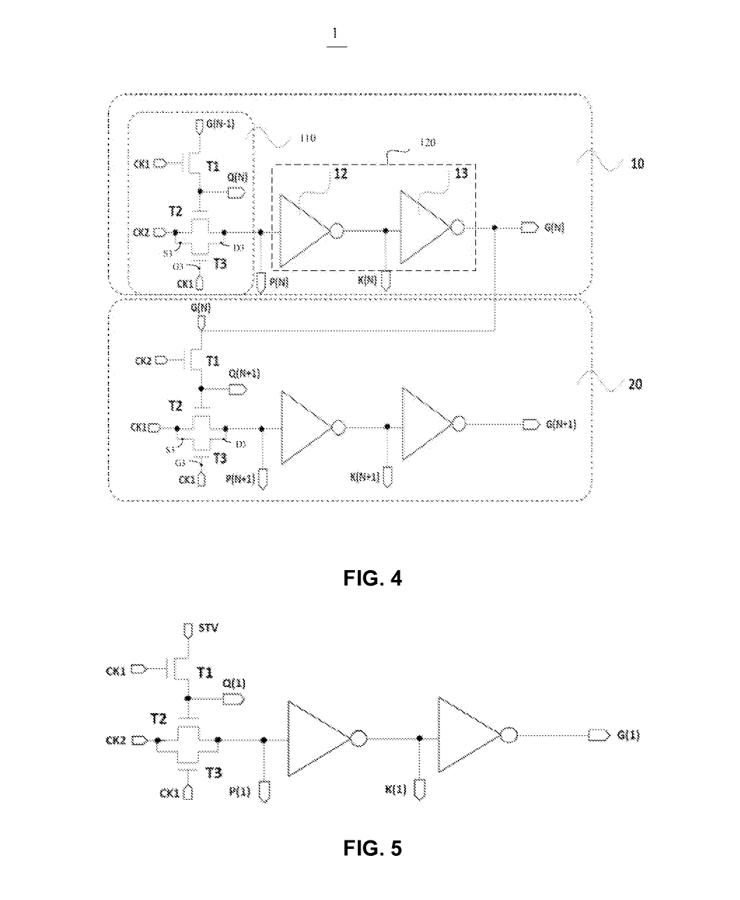

Please also refer to FIG. 4 and FIG. 5. FIG. 4 is a structural diagram of a shift register circuit according to the second preferred embodiment of the present invention. FIG. 5 is a structural diagram of a shift register sub circuit as N=1 in a shift register circuit according to the second preferred embodiment of the present invention. The structure of the shift register circuit in this embodiment and the structure of the shift register circuit in the first embodiment are basically the same. The difference is that in this embodiment, the shift register circuit further comprises a third transistor T3, and the third transistor T3 comprises a third gate G3, a third source S3 and a third drain D3, wherein the third gate G3 receives the first clock signal CK1, and the third source S3 is electrically coupled to the second drain D2, and the third drain D3 is electrically coupled to the second source S2. The structure of the shift register sub circuit as N=1 shown in FIG. 5 and the structure of the shift register sub circuit of the Nth stage shown in FIG. 4 coincide. The repeated description is omitted here. The third transistor T3 can rapidly clear the electric charges at the output end (hear is P(N)) of the shift register sub circuit to make the output waveform to be pulled down to the low voltage level of the second clock signal CK2. In this embodiment, the sequence diagram of the respective signals and the sequence diagram of the respective signals in the first preferred embodiment of the present invention are the same. The repeated description is omitted here.

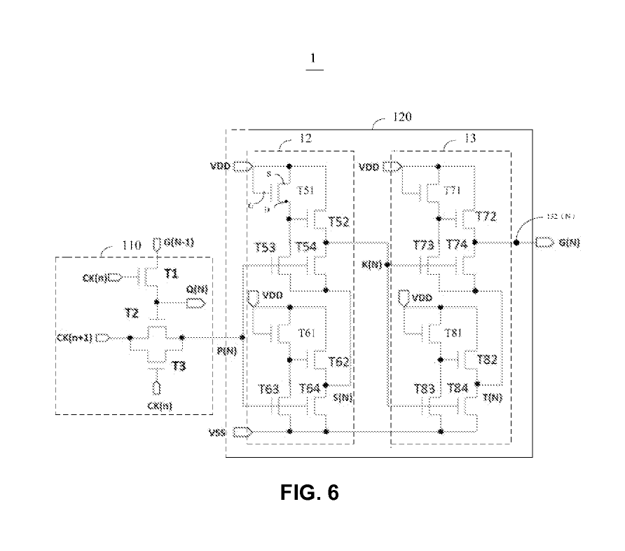

Please also refer to FIG. 6. FIG. 6 is a structural diagram of specific circuit of a shift register sub circuit of a Nth stage in a shift register circuit according to the third preferred embodiment of the present invention. In this embodiment, the structures of the first inverter 12 and the second inverter 13 are the same. The first inverter 12 comprises a first main transistor T51, a second main transistor T52, a third main transistor T53, a fourth main transistor T54, a first auxiliary transistor T61, a second auxiliary transistor T62, a third auxiliary transistor T63 and a fourth auxiliary transistor T64. The first main transistor T51, the second main transistor T52, the third main transistor T53, the fourth main transistor T54, the first auxiliary transistor T61, the second auxiliary transistor T62, the third auxiliary transistor T63 and the fourth auxiliary transistor T64 respectively comprises a gate, a source and a drain. Both the gate G and the source S of the first main transistor T51 are coupled to a high voltage level signal end for receiving a high voltage level signal, and the drain D of the first main transistor T51 is electrically coupled to the gate of the second main transistor T52, and the source of the second main transistor T52 is electrically coupled to the high voltage level signal end VDD, and the drain of the second main transistor T52 is electrically coupled to an output end K(N) of the first inverter 12. The gate of the third main transistor T53 is electrically coupled to the input end P(N) of the first inverter 12, and the source of the third main transistor T53 is electrically coupled to the drain of the first main transistor T51, and the drain of the third main transistor T53 is electrically coupled to the drain of the fourth main transistor T54, and the gate of the fourth main transistor T54 is electrically coupled to the input end P(N) of the first inverter 12, and the source of the fourth main transistor T54 is electrically coupled to the output end K(N) of the first inverter 12. Both the gate and the source of the first auxiliary transistor T61 are electrically coupled to the high voltage level signal end VDD for receiving a high voltage level signal, and the drain of the first auxiliary transistor T61 is electrically coupled to the gate of the second auxiliary transistor T62, and the source of the second auxiliary transistor T62 is electrically coupled to the high voltage level signal end VDD, and the drain of the second auxiliary transistor T62 is electrically coupled to the drain of the fourth main transistor T54. The gate of the third auxiliary transistor T63 is electrically coupled to the input end P(N) of the first inverter 12, and the source of the third auxiliary transistor T63 is electrically coupled to the drain of the first auxiliary transistor T61, and the drain of the third auxiliary transistor T63 is electrically coupled to a low voltage level signal end VSS. The gate of the fourth auxiliary transistor T64 is electrically coupled to the input end P(N) of the first inverter 12, and the source of the fourth auxiliary transistor T64 is electrically coupled to the drain of the second auxiliary transistor T62, and the drain of the fourth auxiliary transistor T64 is electrically coupled to the low voltage level signal end VSS. The first main transistor T51, the second main transistor T52, the third main transistor T53 and the fourth main transistor T54 construct the main inverter part of the first inverter 12. The first auxiliary transistor T61, the second auxiliary transistor T62, the third auxiliary transistor T63 and the fourth auxiliary transistor T64 construct the auxiliary inverter part of the first inverter 12.

The second inverter 13 comprises a first main transistor T71, a second main transistor T72, a third main transistor T73, a fourth main transistor T74, a first auxiliary transistor T81, a second auxiliary transistor T82, a third auxiliary transistor T83 and a fourth auxiliary transistor T84. The first main transistor T71, the second main transistor T72, the third main transistor T73, the fourth main transistor T74, the first auxiliary transistor T81, the second auxiliary transistor T82, the third auxiliary transistor T83 and the fourth auxiliary transistor T84 respectively comprises a gate, a source and a drain. Both the gate and the source of the first main transistor T71 are coupled to the high voltage level signal end VDD for receiving a high voltage level signal, and the drain of the first main transistor T71 is electrically coupled to the gate of the second main transistor T72, and the source of the second main transistor T72 is electrically coupled to the high voltage level signal end VDD, and the drain of the second main transistor T72 is electrically coupled to an output end 132 (N) of the second inverter 13. The gate of the third main transistor T73 is electrically coupled to the output end K(N) of the first inverter 12, and the source of the third main transistor T73 is electrically coupled to the drain of the first main transistor T71, and the drain of the third main transistor T73 is electrically coupled to the drain of the fourth main transistor T74, and the gate of the fourth main transistor T74 is electrically coupled to the input end K(N) of the first inverter 12, and the source of the fourth main transistor T74 is electrically coupled to the output end 132(N) of the second inverter 13, and the drain of the fourth main transistor T74 is electrically coupled to source of the fourth auxiliary transistor T84. The gate and the source of the first auxiliary transistor T81 are electrically coupled to the high voltage level signal end VDD for receiving a high voltage level signal, and the drain of the first auxiliary transistor T81 is electrically coupled to the gate of the second auxiliary transistor T82, and the source of the second auxiliary transistor T82 is electrically coupled to the high voltage level signal end VDD, and the drain of the second auxiliary transistor T82 is electrically coupled to the source of the fourth main transistor T84. The gate of the third auxiliary transistor T83 is electrically coupled to the output end K(N) of the first inverter 12, and the source of the third auxiliary transistor T83 is electrically coupled to the drain of the first auxiliary transistor T81, and the drain of the third auxiliary transistor T83 is electrically coupled to the low voltage level signal end VSS. The gate of the fourth auxiliary transistor T84 is electrically coupled to the output end K(N) of the first inverter 12, and the source of the fourth auxiliary transistor T84 is electrically coupled to the drain of the second auxiliary transistor T82, and the drain of the fourth auxiliary transistor T84 is electrically coupled to the low voltage level signal end VSS. The first main transistor T71, the second main transistor T72, the third main transistor T73 and the fourth main transistor T74 construct the main inverter part of the second inverter 13. The first auxiliary transistor T81, the second auxiliary transistor T82, the third auxiliary transistor T83 and the fourth auxiliary transistor T84 construct the auxiliary inverter part of the second inverter 13.

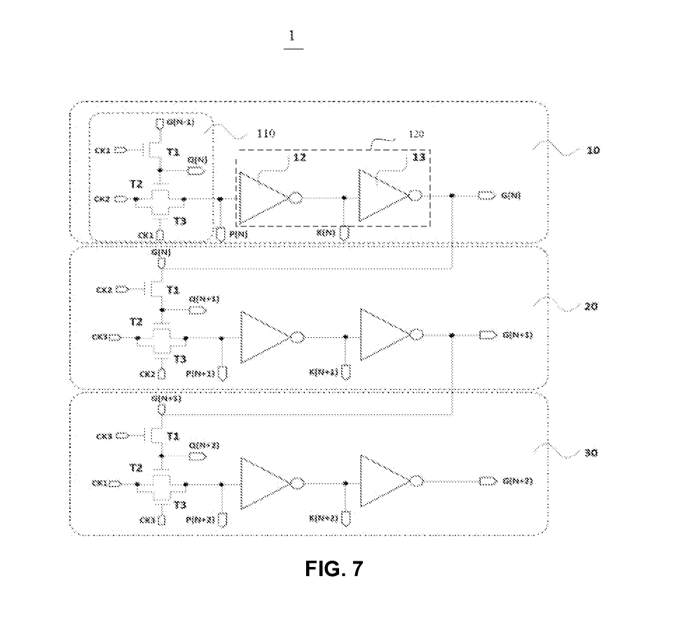

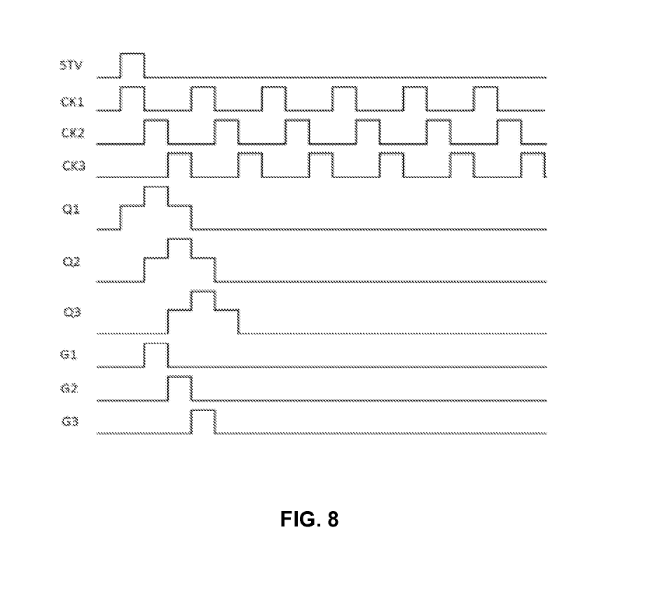

Please also refer to FIG. 7 and FIG. 8. FIG. 7 is a structural diagram of a shift register circuit according to the fourth preferred embodiment of the present invention. FIG. 8 is a time sequence diagram of respective signals in the fourth preferred embodiment of the present invention. In this embodiment, the shift register circuit 1 comprises shift register sub circuits of M stages, wherein M is a multiple of 3 and structures of the shift register sub circuits are the same. That is to say, the shift register sub circuits comprise the same elements, and the connection relationship of the elements in the shift register sub circuits are the same. Here, a shift register sub circuit of a Nth stage 10, a shift register sub circuit of a N+1th stage 20 and a shift register sub circuit of a N+2th stage 30 are illustrated for introduction of the shift register circuit. The structure of the shift register sub circuit 10 of the Nth stage and the structure of the shift register sub circuit of the Nth stage in the shift register circuit according to the second preferred embodiment of the present invention shown in FIG. 4 are the same. The repeated description is omitted here. In this embodiment, the structure of the shift register sub circuit 20 of the N+1th stage and the shift register sub circuit 30 of the N+2th stage in this embodiment and the structure of the shift register sub circuit 10 of the Nth stage are the same. The difference is that, the clock signals loaded to the respective transistors in the shift register sub circuit 20 of the N+1th stage and the shift register sub circuit 30 of the N+2th stage and the clock signals loaded to the respective transistors in the shift register sub circuit 10 of the Nth stage are different. In this embodiment, in the shift register sub circuit 10 of the Nth stage, the gate of the first transistor T1 is loaded with the first clock signal CK1. The drain of the second transistor T2 is loaded with the second clock signal CK2. The gate of the third transistor T3 is loaded with the third clock signal CK3. In the shift register sub circuit 20 of the N+1th stage, the gate of the first transistor T1 is loaded with the second clock signal CK2. The drain of the second transistor T2 is loaded with the third clock signal CK3. The gate of the third transistor T3 is loaded with the second clock signal CK2. All the first clock signal CK1, the second clock signal CK2 and the third clock signal CK3 are square wave signals. All the duty ratios of the first clock signal CK1, the second clock signal CK2 and the third clock signal CK3 are smaller than 1. The high voltage levels of the first clock signal CK1, the second clock signal CK2 and the third clock signal CK3 do not coincide with one another. The high voltage level of the second clock signal CK2 delays than the high voltage level of the first clock signal CK1, and the start point of the second clock signal CK2 is the same as the finish point of the first clock signal CK1. The high voltage level of the third clock signal CK3 delays than the high voltage level of the second clock signal CK2, and the start point of the third clock signal CK3 is the same as the finish point of the second clock signal CK2.

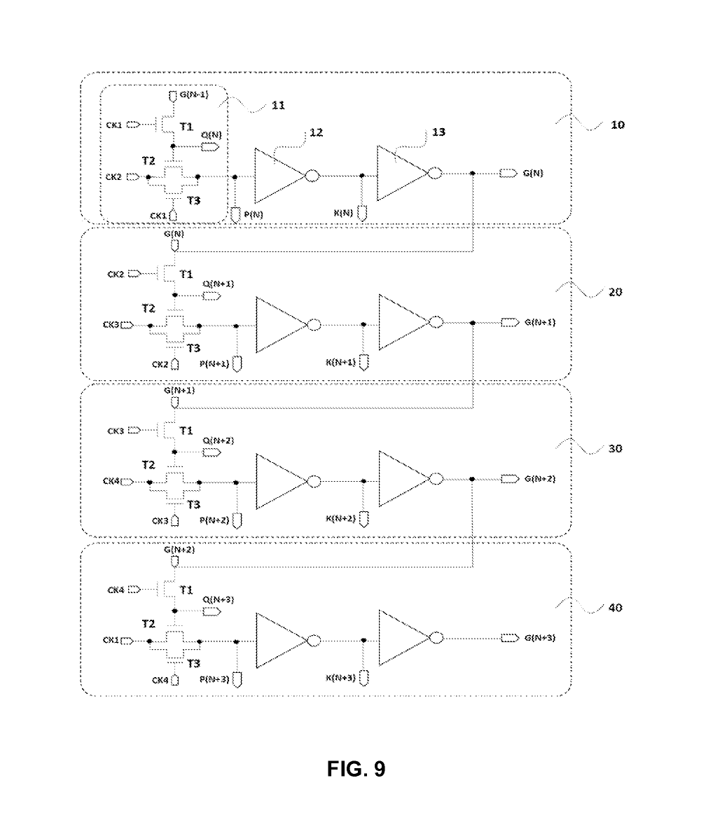

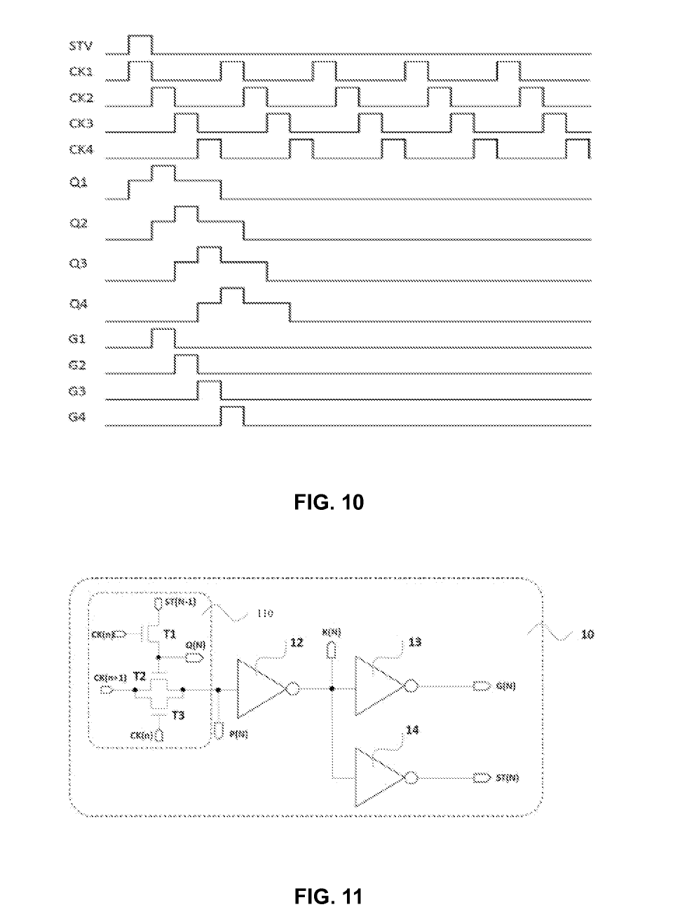

Please also refer to FIG. 9 and FIG. 10. FIG. 9 is a structural diagram of a shift register circuit according to the fifth preferred embodiment of the present invention. FIG. 10 is a time sequence diagram of respective signals in the fifth preferred embodiment of the present invention. In this embodiment, the shift register circuit comprises shift register sub circuits of M stages, wherein M is a multiple of 4 and structures of the shift register sub circuits are the same. That is to say, the shift register sub circuits comprise the same elements, and the connection relationship of the elements in the shift register sub circuits are the same. Here, a shift register sub circuit of a Nth stage 10, a shift register sub circuit of a N+1th stage 20, a shift register sub circuit of a N+2th stage 30 and a shift register sub circuit of a N+3th stage 40 are illustrated for introduction of the shift register circuit. In this embodiment, the structure of the shift register sub circuit 10 of the Nth stage and the structure of the shift register sub circuit of the Nth stage in the shift register circuit according to the second preferred embodiment of the present invention shown in FIG. 4 are the same. The repeated description is omitted here. In this embodiment, the structure of the shift register sub circuit 20 of the N+1th stage, the shift register sub circuit 30 of the N+2th stage and the shift register sub circuit 40 of the N+3th stage in this embodiment and the structure of the shift register sub circuit 10 of the Nth stage are the same. The difference is that, the clock signals loaded to the respective transistors in the shift register sub circuit 20 of the N+1th stage and the shift register sub circuit 30 of the N+2th stage and the shift register sub circuit 40 of the N+3th stage and the clock signals loaded to the respective transistors in the shift register sub circuit 10 of the Nth stage are different. In this embodiment, in the shift register sub circuit 10 of the Nth stage, the gate of the first transistor T1 is loaded with the first clock signal CK1. The drain of the second transistor T2 is loaded with the second clock signal CK2. The gate of the third transistor T3 is loaded with the third clock signal CK3.In the shift register sub circuit 20 of the N+1th stage, the gate of the first transistor T1 is loaded with the second clock signal CK2. The drain of the second transistor T2 is loaded with the third clock signal CK3. The gate of the third transistor T3 is loaded with the second clock signal CK2.In the shift register sub circuit 30 of the N+2th stage, the gate of the first transistor T1 is loaded with the third clock signal CK3. The drain of the second transistor T2 is loaded with the fourth clock signal CK4. The gate of the third transistor T3 is loaded with the third clock signal CK3. In the shift register sub circuit 40 of the N+3th stage, the gate of the first transistor T1 is loaded with the fourth clock signal CK4. The drain of the second transistor T2 is loaded with the first clock signal CK1. The gate of the third transistor T3 is loaded with the fourth clock signal CK4. All the first clock signal CK1, the second clock signal CK2, the third clock signal CK3 and the fourth clock signal CK4 are square wave signals. All the duty ratios of the first clock signal CK1, the second clock signal CK2, the third clock signal CK3 and the fourth clock signal CK4 are smaller than 1. The high voltage levels of the first clock signal CK1, the second clock signal CK2, the third clock signal CK3 and the fourth clock signal CK4 do not coincide with one another. The high voltage level of the second clock signal CK2 delays than the high voltage level of the first clock signal CK1, and the start point of the second clock signal CK2 is the same as the finish point of the first clock signal CK1. The high voltage level of the third clock signal CK3 delays than the high voltage level of the second clock signal CK2, and the start point of the third clock signal CK3 is the same as the finish point of the second clock signal CK2. The high voltage level of the fourth clock signal CK4 delays than the high voltage level of the third clock signal CK3, and the start point of the fourth clock signal CK4 is the same as the finish point of the third clock signal CK3. Preferably, all the duty ratios of the first clock signal CK1, the second clock signal CK2, the third clock signal CK3 and the fourth clock signal CK4 are 1/3.

Please also refer to FIG. 11. FIG. 11 is a structural diagram of a shift register sub circuit of a Nth stage in a shift register circuit according to the sixth preferred embodiment of the present invention. In this embodiment, the shift register sub circuit of the Nth stage comprises a control signal input end G(N−1 of the Nth stage, a clock signal output control circuit 110, a buffer 120 and a signal output end G(N of the Nth stage. The control signal input end G(N−1) of the Nth stage is employed to receive an output signal of a shift register sub circuit of a N−1th stage. The clock signal output control circuit 110 comprises a first transistor T1, a second transistor T2 and a third transistor T3, and the first transistor T1 comprises a first gate G1, a first source S1 and a first drain D1, and the second transistor T2 comprises a second gate G2, a second source S2 and a second rain D2, and the third transistor T3 comprises a third gate G3, a third source S3 and a third rain D3. The gate of the first transistor T1 receives a Nth clock signal CK(N), and the first source S1 is coupled to the control signal output end G(N−1) of the Nth stage to receive the output signal of the shift register sub circuit of the N−1th stage, and the first drain D1 is electrically coupled to the second gate G2 via a node Q(N). The first transistor T1 transmits the output signal of the shift register sub circuit of the N−1th stage to the node Q(N) under control of the Nth clock signal CK(N).The second drain D2 receives a N+1th clock signal CK(N+1), and the second transistor T2 transmits the N+1th clock signal CK(N+1) to the second source S2 under control of the output signal of the shift register sub circuit of the N−1th stage. The second source S2 is employed to be an output end of the clock signal output control circuit 11 to be electrically coupled to the buffer 120. The buffer 120 is employed to buffer an signal outputted by the second source S2 with a predetermined period to obtain an output signal of the shift register sub circuit of the Nth stage and outputs the same via the signal output end G(N) of the Nth stage. Both the Nth clock signal CK(N) and the N+1th clock signal CK(N+1) are square wave signals, and a high voltage level of the Nth clock signal CK(N) and a high voltage level of the N+1th clock signal CK(N+1) do not coincide.

The buffer 120 comprises a first inverter 12 and a second inverter 13 sequentially coupled in series, and an input end of the first inverter 12 is coupled to the second source S2 to receive the output signal of the clock signal output control circuit 110. The first inverter 12 is employed to invert the output signal of the clock signal output control circuit 110. The second inverter 13 is employed to invert the output signal from the first inverter 12. Therefore, the waveform of the signal outputted from the output end of the second inverter 13 coincides with the waveform of the output signal of the clock signal output control circuit 110 but the signal outputted by the second inverter 13 delays the predetermined period than the output signal of the clock signal output control circuit 110 after passing through the first inverter 12 and the second inverter 13. An output end of the second inverter 13 is coupled to the signal output end G(N) of the Nth stage to output the output signal of the shift register sub circuit of the Nth stage via the signal output end G(N) of the Nth stage. The buffer 120 comprising two inverters, the first inverter 12 and the second inverter 13 can effectively prevent the influence of the clock signals of the clock output control circuit 110 to the output signal from the output end of the shift register sub circuit of the Nth stage.

In this embodiment, the buffer 120 further comprises a third inverter 14, and an input end of the third inverter 14 is electrically coupled to a node between the first inverter 12 and the second inverter 13, and an output end of the third inverter 14 is electrically coupled to a stage transfer node ST(N), and a signal outputted from the output end of the third inverter 14 is transmitted to the shift register sub circuit of the next stage via the stage transfer node ST(N). Thus, the loading of the Nth signal output end G(N) can be reduced.

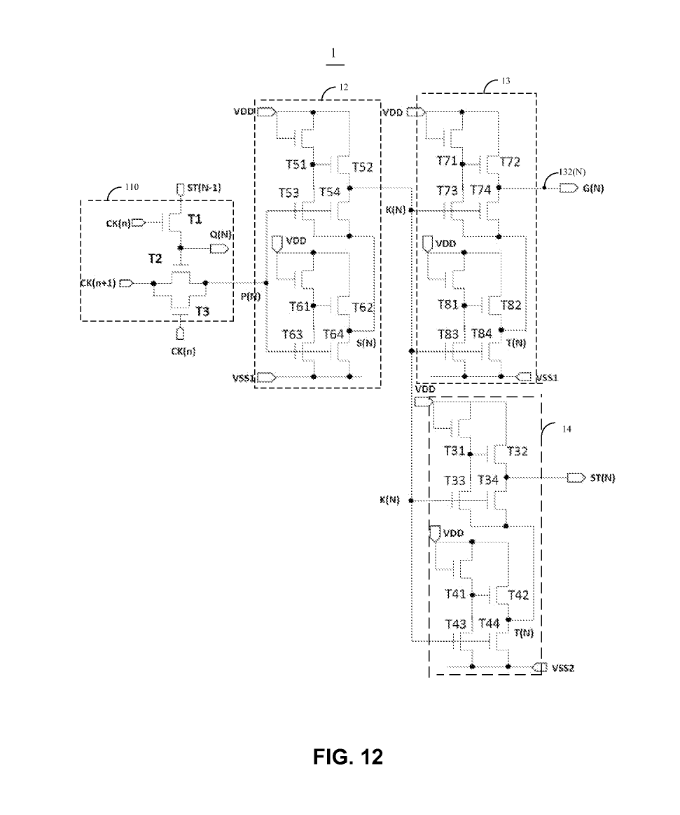

FIG. 12 is a structural diagram of specific circuit of a shift register sub circuit of a Nth stage in a shift register circuit according to the sixth preferred embodiment of the present invention. In this embodiment, the clock signal output control circuit 110 and the clock signal output control circuit 110 shown in FIG. 11 are the same. The repeated description is omitted here. The structures of the first inverter 12, the second inverter 13 and the third inverter 14 are the same. Here, the first inverter 12, the second inverter 13 and the third inverter 14 are introduced in detail.

The first inverter 12 comprises a first main transistor T51, a second main transistor T52, a third main transistor T53, a fourth main transistor T54, a first auxiliary transistor T61, a second auxiliary transistor T62, a third auxiliary transistor T63 and a fourth auxiliary transistor T64. The first main transistor T51, the second main transistor T52, the third main transistor T53, the fourth main transistor T54, the first auxiliary transistor T61, the second auxiliary transistor T62, the third auxiliary transistor T63 and the fourth auxiliary transistor T64 respectively comprises a gate, a source and a drain. Both the gate G and the source S of the first main transistor T51 are coupled to a high voltage level signal end for receiving a high voltage level signal, and the drain D of the first main transistor T51 is electrically coupled to the gate of the second main transistor T52, and the source of the second main transistor T52 is electrically coupled to the high voltage level signal end VDD, and the drain of the second main transistor T52 is electrically coupled to an output end K(N) of the first inverter 12. The gate of the third main transistor T53 is electrically coupled to the input end P(N) of the first inverter 12, and the source of the third main transistor T53 is electrically coupled to the drain of the first main transistor T51, and the drain of the third main transistor T53 is electrically coupled to the drain of the fourth main transistor T54, and the gate of the fourth main transistor T54 is electrically coupled to the input end P(N) of the first inverter 12, and the source of the fourth main transistor T54 is electrically coupled to the output end K(N) of the first inverter 12. Both the gate and the source of the first auxiliary transistor T61 are electrically coupled to the high voltage level signal end VDD for receiving a high voltage level signal, and the drain of the first auxiliary transistor T61 is electrically coupled to the gate of the second auxiliary transistor T62, and the source of the second auxiliary transistor T62 is electrically coupled to the high voltage level signal end VDD, and the drain of the second auxiliary transistor T62 is electrically coupled to the drain of the fourth main transistor T54. The gate of the third auxiliary transistor T63 is electrically coupled to the input end P(N) of the first inverter 12, and the source of the third auxiliary transistor T63 is electrically coupled to the drain of the first auxiliary transistor T61, and the drain of the third auxiliary transistor T63 is electrically coupled to a low voltage level signal end VSS1. The gate of the fourth auxiliary transistor T64 is electrically coupled to the input end P(N) of the first inverter 12, and the source of the fourth auxiliary transistor T64 is electrically coupled to the drain of the second auxiliary transistor T62, and the drain of the fourth auxiliary transistor T64 is electrically coupled to the low voltage level signal end VSS1. The first main transistor T51, the second main transistor T52, the third main transistor T53 and the fourth main transistor T54 construct the main inverter part of the first inverter 12. The first auxiliary transistor T61, the second auxiliary transistor T62, the third auxiliary transistor T63 and the fourth auxiliary transistor T64 construct the auxiliary inverter part of the first inverter 12.

The second inverter 13 comprises a first main transistor T71, a second main transistor T72, a third main transistor T73, a fourth main transistor T74, a first auxiliary transistor T81, a second auxiliary transistor T82, a third auxiliary transistor T83 and a fourth auxiliary transistor T84. The first main transistor T71, the second main transistor T72, the third main transistor T73, the fourth main transistor T74, the first auxiliary transistor T81, the second auxiliary transistor T82, the third auxiliary transistor T83 and the fourth auxiliary transistor T84 respectively comprises a gate, a source and a drain. Both the gate and the source of the first main transistor T71 are coupled to the high voltage level signal end VDD for receiving a high voltage level signal, and the drain of the first main transistor T71 is electrically coupled to the gate of the second main transistor T72, and the source of the second main transistor T72 is electrically coupled to the high voltage level signal end VDD, and the drain of the second main transistor T72 is electrically coupled to an output end 132 (N) of the second inverter 13. The gate of the third main transistor T73 is electrically coupled to the output end K(N) of the first inverter 12, and the source of the third main transistor T73 is electrically coupled to the drain of the first main transistor T71, and the drain of the third main transistor T73 is electrically coupled to the drain of the fourth main transistor T74, and the gate of the fourth main transistor T74 is electrically coupled to the input end K(N) of the first inverter 12, and the source of the fourth main transistor T74 is electrically coupled to the output end 132(N) of the second inverter 13, and the drain of the fourth main transistor T74 is electrically coupled to source of the fourth auxiliary transistor T84. The gate and the source of the first auxiliary transistor T81 are electrically coupled to the high voltage level signal end VDD for receiving a high voltage level signal, and the drain of the first auxiliary transistor T81 is electrically coupled to the gate of the second auxiliary transistor T82, and the source of the second auxiliary transistor T82 is electrically coupled to the high voltage level signal end VDD, and the drain of the second auxiliary transistor T82 is electrically coupled to the source of the fourth main transistor T84. The gate of the third auxiliary transistor T83 is electrically coupled to the output end K(N) of the first inverter 12, and the source of the third auxiliary transistor T83 is electrically coupled to the drain of the first auxiliary transistor T81, and the drain of the third auxiliary transistor T83 is electrically coupled to the low voltage level signal end VSS1. The gate of the fourth auxiliary transistor T84 is electrically coupled to the output end K(N) of the first inverter 12, and the source of the fourth auxiliary transistor T84 is electrically coupled to the drain of the second auxiliary transistor T82, and the drain of the fourth auxiliary transistor T84 is electrically coupled to the low voltage level signal end VSS1. The first main transistor T71, the second main transistor T72, the third main transistor T73 and the fourth main transistor T74 construct the main inverter part of the second inverter 13. The first auxiliary transistor T81, the second auxiliary transistor T82, the third auxiliary transistor T83 and the fourth auxiliary transistor T84 construct the auxiliary inverter part of the second inverter 13.

The third inverter 14 comprises a first main transistor T31, a second main transistor T32, a third main transistor T33, a fourth main transistor T34, a first auxiliary transistor T41, a second auxiliary transistor T42, a third auxiliary transistor T43 and a fourth auxiliary transistor T44. The first main transistor T31, the second main transistor T32, the third main transistor T33, the fourth main transistor T34, the first auxiliary transistor T41, the second auxiliary transistor T42, the third auxiliary transistor T43 and the fourth auxiliary transistor T44 respectively comprises a gate, a source and a drain. Both the gate and the source of the first main transistor T31 are coupled to a high voltage level signal end VDD for receiving a high voltage level signal, and the drain of the first main transistor T31 is electrically coupled to the gate of the second main transistor T32, and the source of the second main transistor T32 is electrically coupled to the high voltage level signal end VDD, and the drain of the second main transistor T32 is electrically coupled to the stage transfer node ST(N). The gate of the third main transistor T33 is electrically coupled to the output end K(N) of the first inverter 12, and the source of the third main transistor T33 is electrically coupled to the drain of the first main transistor T31, and the drain of the third main transistor T33 is electrically coupled to the drain of the fourth main transistor T34, and the gate of the fourth main transistor T34 is electrically coupled to the output end K(N) of the first inverter 12, and the source of the fourth main transistor T34 is electrically coupled to the stage transfer node ST(N), and the drain of the fourth main transistor T34 is electrically coupled to the source of the fourth auxiliary transistor T44. Both the gate and the source of the first auxiliary transistor T41 are electrically coupled to the high voltage level signal end VDD for receiving a high voltage level signal, and the drain of the first auxiliary transistor T41 is electrically coupled to the gate of the second auxiliary transistor T42, and the source of the second auxiliary transistor T42 is electrically coupled to the high voltage level signal end VDD, and the drain of the second auxiliary transistor T42 is electrically coupled to the source of the fourth auxiliary transistor T44. The gate of the third auxiliary transistor T43 is electrically coupled to the output end K(N) of the first inverter 12, and the source of the third auxiliary transistor T43 is electrically coupled to the drain of the first auxiliary transistor T41, and the drain of the third auxiliary transistor T43 is electrically coupled to a low voltage level signal end VSS2. The gate of the fourth auxiliary transistor T44 is electrically coupled to the output end K(N) of the first inverter 12, and the source of the fourth auxiliary transistor T44 is electrically coupled to the drain of the second auxiliary transistor T42, and the drain of the fourth auxiliary transistor T44 is electrically coupled to the low voltage level signal end VSS2. The first main transistor T31, the second main transistor T32, the third main transistor T33 and the fourth main transistor T34 construct the main inverter part of the third inverter 14. The first auxiliary transistor T41, the second auxiliary transistor T42, the third auxiliary transistor T43 and the fourth auxiliary transistor T44 construct the auxiliary inverter part of the third inverter 14. In one embodiment, the low voltage level signal end VSS1 and the low voltage level signal end VSS2 are loaded with the low voltage level signals of the same voltage level.

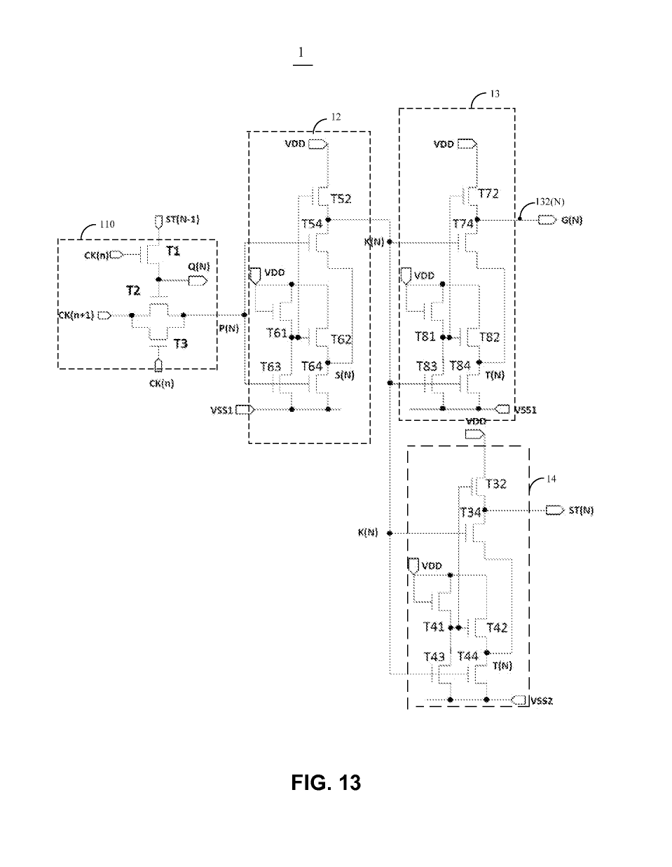

FIG. 13 is a structural diagram of specific circuit of a shift register sub circuit of a Nth stage in a shift register circuit according to the seventh preferred embodiment of the present invention. In this embodiment, the clock signal output control circuit 110 and the clock signal output control circuit 110 shown in FIG. 11 are the same. The repeated description is omitted herein this embodiment, the structures of the first inverter 12, the second inverter 13 and the third inverter 14 are the same. Here, the first inverter 12, the second inverter 13 and the third inverter 14 are introduced in detail.

Compared with the structural diagram of specific circuit of the shift register sub circuit of the Nth stage in the shift register circuit according to the sixth preferred embodiment shown in FIG. 12, the clock signal output control circuit 110 in the specific circuit structure of the Nth shift register sub circuit in this embodiment and the clock signal output control circuit 110 in the sixth preferred embodiment shown in FIG. 12 are the same. The repeated description is omitted here. The structures of the first inverter 12, the second inverter 13 and the third inverter 14 comprise the same elements. In this embodiment, the first inverter 12 merely comprises a second main transistor T52, a fourth main transistor T54, a first auxiliary transistor T61, a second auxiliary transistor T62, a third auxiliary transistor T63 and a fourth auxiliary transistor T64. The second main transistor T52, the fourth main transistor T54, the first auxiliary transistor T61, the second auxiliary transistor T62, the third auxiliary transistor T63 and the fourth auxiliary transistor T64 respectively comprises a gate, a source and a drain. The gate of the second main transistor T52 is electrically coupled to the drain of the first auxiliary transistor T61, and the source of the second main transistor T52 is electrically coupled to a high voltage level signal end VDD for receiving a high voltage level signal, and the drain of the second main transistor T52 is electrically coupled to an output end K(N) of the first inverter 12. The gate of the fourth main transistor T54 is electrically coupled to the input end P(N) of the first inverter 12, and the source of the fourth main transistor T54 is electrically coupled to the output end K(N) of the first inverter 12, and the drain of the fourth main transistor T54 is electrically coupled to the drain of the second auxiliary transistor T62. Both the gate and the source of the first auxiliary transistor T61 are electrically coupled to the high voltage level signal end VDD for receiving a high voltage level signal, and the drain of the first auxiliary transistor T61 is electrically coupled to the gate of the second auxiliary transistor T62, and the source of the second auxiliary transistor T62 is electrically coupled to the high voltage level signal end VDD for receiving a high voltage level signal, and the drain of the second auxiliary transistor T62 is electrically coupled to the source of the fourth auxiliary transistor T64. The gate of the third auxiliary transistor T63 is electrically coupled to the input end P(N) of the first inverter 12, and the source of the third auxiliary transistor T63 is electrically coupled to the drain of the first auxiliary transistor T61, and the drain of the third auxiliary transistor T63 is electrically coupled to a low voltage level signal end VSS1. The gate of the fourth auxiliary transistor T64 is electrically coupled to the input end P(N) of the first inverter 12, and the source of the fourth auxiliary transistor T64 is electrically coupled to the drain of the second auxiliary transistor T62, and the drain of the fourth auxiliary transistor T64 is electrically coupled to the low voltage level signal end VSS1.

The second inverter 13 merely comprises a second main transistor T72, a fourth main transistor T74, a first auxiliary transistor T81, a second auxiliary transistor T82, a third auxiliary transistor T83 and a fourth auxiliary transistor T84. The second main transistor T72, the fourth main transistor T74, the first auxiliary transistor T81, the second auxiliary transistor T82, the third auxiliary transistor T83 and the fourth auxiliary transistor T84 respectively comprises a gate, a source and a drain. The gate of the second main transistor T72 is electrically coupled to the drain of the first auxiliary transistor T81, and the source of the second main transistor T72 is electrically coupled to the high voltage level signal end VDD, and the drain of the second main transistor T72 is electrically coupled to an output end 132(N) of the second inverter 13. The gate of the fourth main transistor T74 is electrically coupled to the output end K(N) of the first inverter 12, and the source of the fourth main transistor T74 is electrically coupled to the output end 132(N) of the second inverter 13, and the drain of the fourth main transistor T74 is electrically coupled to drain of the second auxiliary transistor T82. The gate and the source of the first auxiliary transistor T81 are electrically coupled to a high voltage level signal end VDD, and the drain of the first auxiliary transistor T81 is electrically coupled to the gate of the second auxiliary transistor T82, and the source of the second auxiliary transistor T82 is electrically coupled to the high voltage level signal end VDD, and the drain of the second auxiliary transistor T82 is electrically coupled to the source of the fourth main transistor T84. The gate of the third auxiliary transistor T83 is electrically coupled to the output end K(N) of the first inverter 12, and the source of the third auxiliary transistor T83 is electrically coupled to the drain of the first auxiliary transistor T81, and the drain of the third auxiliary transistor T83 is electrically coupled to the low voltage level signal end VSS1. The gate of the fourth auxiliary transistor T84 is electrically coupled to the output end K(N) of the first inverter 12, and the source of the fourth auxiliary transistor T84 is electrically coupled to the drain of the second auxiliary transistor T82, and the drain of the fourth auxiliary transistor T84 is electrically coupled to the low voltage level signal end VSS1.

The third inverter 14 merely comprises a second main transistor T32, a fourth main transistor T34, a first auxiliary transistor T41, a second auxiliary transistor T42, a third auxiliary transistor T43 and a fourth auxiliary transistor T44. The second main transistor T32, the fourth main transistor T34, the first auxiliary transistor T41, the second auxiliary transistor T42, the third auxiliary transistor T43 and the fourth auxiliary transistor T44 respectively comprises a gate, a source and a drain. The gate of the second main transistor T32 is electrically coupled to the drain of the first auxiliary transistor T41, and the source of the second main transistor T32 is electrically coupled to the high voltage level signal end VDD, and the drain of the second main transistor T32 is electrically coupled to the stage transfer node ST(N). The gate of the fourth main transistor T34 is electrically coupled to the output end K(N) of the first inverter 12, and the source of the fourth main transistor T34 is electrically coupled to the stage transfer node ST(N), and the drain of the fourth main transistor T34 is electrically coupled to the drain of the second auxiliary transistor T42. Both the gate and the source of the first auxiliary transistor T41 are electrically coupled to a high voltage level signal end VDD, and the drain of the first auxiliary transistor T41 is electrically coupled to the gate of the second auxiliary transistor T42, and the source of the second auxiliary transistor T42 is electrically coupled to the high voltage level signal end VDD, and the drain of the second auxiliary transistor T42 is electrically coupled to the source of the fourth auxiliary transistor T44. The gate of the third auxiliary transistor T43 is electrically coupled to the output end K(N) of the first inverter 12, and the source of the third auxiliary transistor T43 is electrically coupled to the drain of the first auxiliary transistor T41, and the drain of the third auxiliary transistor T43 is electrically coupled to a low voltage level signal end VSS2.The gate of the fourth auxiliary transistor T44 is electrically coupled to the output end K(N) of the first inverter 12, and the source of the fourth auxiliary transistor T44 is electrically coupled to the drain of the second auxiliary transistor T42, and the drain of the fourth auxiliary transistor T44 is electrically coupled to the low voltage level signal end VSS2.

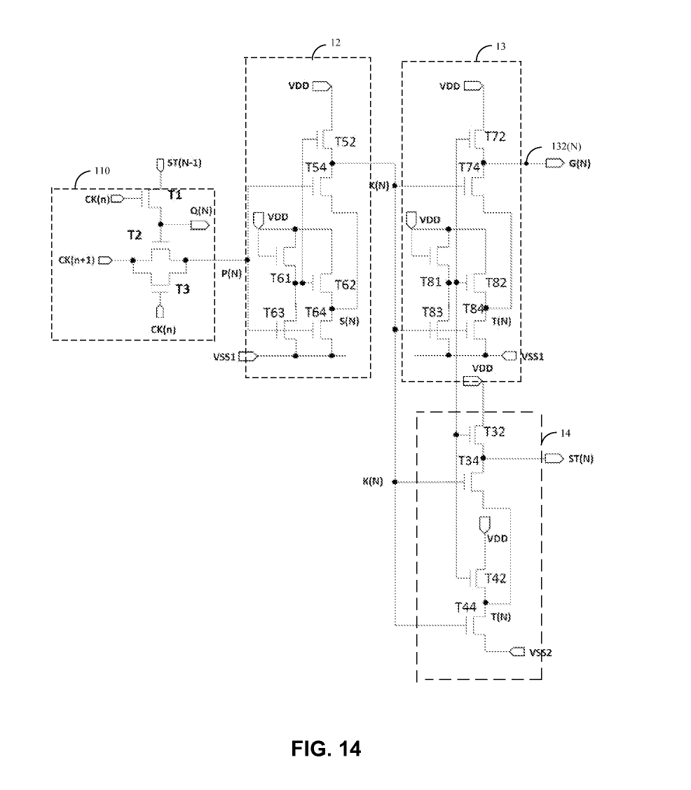

Please refer to FIG. 14. FIG. 14 is a structural diagram of specific circuit of a shift register sub circuit of a Nth stage in a shift register circuit according to the eighth preferred embodiment of the present invention. The clock signal output control circuit 110 in the specific circuit structure of the Nth shift register sub circuit in this embodiment and the clock signal output control circuit 110 in the sixth preferred embodiment shown in FIG. 12 are the same. The repeated description is omitted here. In this embodiment, the first inverter 12 and the second inverter 13 comprise the same elements. The elements of the third inverter 14 and the elements in the first inverter 12 and the second inverter 13 are different. In this embodiment, the first inverter 12 merely comprises a second main transistor T52, a fourth main transistor T54, a first auxiliary transistor T61, a second auxiliary transistor T62, a third auxiliary transistor T63 and a fourth auxiliary transistor T64. The second main transistor T52, the fourth main transistor T54, the first auxiliary transistor T61, the second auxiliary transistor T62, the third auxiliary transistor T63 and the fourth auxiliary transistor T64 respectively comprises a gate, a source and a drain. The gate of the second main transistor T52 is electrically coupled to the drain of the first auxiliary transistor T61, and the source of the second main transistor T52 is electrically coupled to a high voltage level signal end VDD for receiving a high voltage level signal, and the drain of the second main transistor T52 is electrically coupled to an output end K(N) of the first inverter 12. The gate of the fourth main transistor T54 is electrically coupled to the input end P(N) of the first inverter 12, and the source of the fourth main transistor T54 is electrically coupled to the output end K(N) of the first inverter 12, and the drain of the fourth main transistor T54 is electrically coupled to the drain of the second auxiliary transistor T62. Both the gate and the source of the first auxiliary transistor T61 are electrically coupled to the high voltage level signal end VDD for receiving a high voltage level signal, and the drain of the first auxiliary transistor T61 is electrically coupled to the gate of the second auxiliary transistor T62, and the source of the second auxiliary transistor T62 is electrically coupled to the high voltage level signal end VDD, and the drain of the second auxiliary transistor T62 is electrically coupled to the drain of the fourth main transistor T54. The gate of the third auxiliary transistor T63 is electrically coupled to the input end P(N) of the first inverter 12, and the source of the third auxiliary transistor T63 is electrically coupled to the drain of the first auxiliary transistor T61, and the drain of the third auxiliary transistor T63 is electrically coupled to a low voltage level signal end VSS1.The gate of the fourth auxiliary transistor T64 is electrically coupled to the input end P(N) of the first inverter 12, and the source of the fourth auxiliary transistor T64 is electrically coupled to the drain of the second auxiliary transistor T62, and the drain of the fourth auxiliary transistor T64 is electrically coupled to the low voltage level signal end VSS1.

The second inverter 13 merely comprises a second main transistor T72, a fourth main transistor T74, a first auxiliary transistor T81, a second auxiliary transistor T82, a third auxiliary transistor T83 and a fourth auxiliary transistor T84. The second main transistor T72, the fourth main transistor T74, the first auxiliary transistor T81, the second auxiliary transistor T82, the third auxiliary transistor T83 and the fourth auxiliary transistor T84 respectively comprises a gate, a source and a drain. The gate of the second main transistor T72 is electrically coupled to the drain of the first auxiliary transistor T81, and the source of the second main transistor T72 is electrically coupled to the high voltage level signal end VDD, and the drain of the second main transistor T72 is electrically coupled to an output end 132(N) of the second inverter 13. The gate of the fourth main transistor T74 is electrically coupled to the output end K(N) of the first inverter 12, and the source of the fourth main transistor T74 is electrically coupled to the output end 132(N) of the second inverter 13, and the drain of the fourth main transistor T74 is electrically coupled to drain of the second auxiliary transistor T82. The gate and the source of the first auxiliary transistor T81 are electrically coupled to a high voltage level signal end VDD, and the drain of the first auxiliary transistor T81 is electrically coupled to the gate of the second auxiliary transistor T82, and the source of the second auxiliary transistor T82 is electrically coupled to the high voltage level signal end VDD, and the drain of the second auxiliary transistor T82 is electrically coupled to the source of the fourth main transistor T84. The gate of the third auxiliary transistor T83 is electrically coupled to the output end K(N) of the first inverter 12, and the source of the third auxiliary transistor T83 is electrically coupled to the drain of the first auxiliary transistor T81, and the drain of the third auxiliary transistor T83 is electrically coupled to the low voltage level signal end VSS1. The gate of the fourth auxiliary transistor T84 is electrically coupled to the output end K(N) of the first inverter 12, and the source of the fourth auxiliary transistor T84 is electrically coupled to the drain of the second auxiliary transistor T82, and the drain of the fourth auxiliary transistor T84 is electrically coupled to the low voltage level signal end VSS1.

The third inverter 14 merely comprises a second main transistor T32, a fourth main transistor T34, a second auxiliary transistor T42 and a fourth auxiliary transistor T44. The second main transistor T32, the fourth main transistor T34, the second auxiliary transistor T42 and the fourth auxiliary transistor T44 respectively comprises a gate, a source and a drain. The gate of the second main transistor T32 is electrically coupled to the gate of the second main transistor T72 in the second inverter 13, and the source of the second main transistor T32 is electrically coupled to the high voltage level signal end VDD, and the drain of the second main transistor T32 is electrically coupled to the stage transfer node ST(N). The gate of the fourth main transistor T34 is electrically coupled to the output end K(N) of the first inverter 12, and the source of the fourth main transistor T34 is electrically coupled to the stage transfer node ST(N), and the drain of the fourth main transistor T34 is electrically coupled to the drain of the second auxiliary transistor T42.The gate of the second auxiliary transistor T42 is electrically coupled to the gate of the second main transistor T32, and the source of the second auxiliary transistor T42 is electrically coupled to the high voltage level signal end VDD, and the drain of the second auxiliary transistor T42 is electrically coupled to the source of the fourth auxiliary transistor T44, and the gate of the fourth auxiliary transistor T44 is electrically coupled to the output end K(N) of the first inverter 12, and the drain of the fourth auxiliary transistor T44 is electrically coupled to the low voltage level signal end VSS2 for receiving a low voltage level signal.

Above are embodiments of the present invention, which does not limit the scope of the present invention. Any modifications, equivalent replacements or improvements within the spirit and principles of the embodiment described above should be covered by the protected scope of the invention.

What is claimed is:

1. A shift register circuit, wherein the shift register circuit comprises shift register sub circuits of M stages, and a shift register sub circuit of a Nth stage comprises a control signal input end of the Nth stage, a clock signal output control circuit, a buffer and a signal output end of the Nth stage which are electrically coupled in sequence, and the control signal input end of the Nth stage is employed to receive an output signal of a shift register sub circuit of a N−1th stage, and the clock signal output control circuit comprises a first transistor and a second transistor, and the first transistor comprises a first gate, a first source and a first drain, and the second transistor comprises a second gate, a second source and a second rain, and the first gate receives a first clock signal, and the source is coupled to the signal output end of the Nth stage to receive the output signal of the shift register sub circuit of the N−1th stage, and the first drain is electrically coupled to the second gate via a node, and the first transistor transmits the output signal of the shift register sub circuit of the N−1th stage to the node under control of the first clock signal, and the second drain receives a second clock signal, and the second transistor transmits the second clock signal to the second source under control of the output signal of the shift register sub circuit of the N−1th stage, and the second source is employed to be an output end of the clock signal output control circuit to be electrically coupled to the buffer, and the buffer is employed to buffer an signal outputted by the second source with a predetermined period to obtain an output signal of the shift register sub circuit of the Nth stage and outputs the same via the signal output end of the Nth stage, wherein both the first clock signal and the second clock signal are square wave signals, and a high voltage level of the first clock signal and a high voltage level of the second clock signal do not coincide, and a duty ratio of the first clock signal is smaller than 1, and a duty ratio of the second clock signal is smaller than 1, and M and N are natural numbers, and M is greater than or equal to N.

2. The shift register circuit according to claim 1, wherein the shift register circuit further comprises a shift register sub circuit of a N+1th stage, and the shift register sub circuit of the N+1th stage comprises the same elements of the shift register sub circuit of the Nth stage, and a first gate of a first transistor in the shift register sub circuit of the N+1th stage receives the second clock signal, and a second drain of a second transistor in the shift register sub circuit of the N+1th stage receives the first clock signal.

3. The shift register circuit according to claim 1, wherein each shift register circuit further comprises a third transistor, and the third transistor comprises a third gate, a third source and a third drain, wherein the third gate receives the same clock signal of the first gate of the first transistor, and the third source is electrically coupled to the second drain, and the third drain is electrically coupled to the second source.

4. The shift register circuit according to claim 3, wherein the shift register circuit further comprises a shift register sub circuit of a N+1th stage and a shift register sub circuit of a N+2th stage, and the shift register sub circuit of the N+1th stage and the shift register sub circuit of the N+2th stage comprise the same elements of the shift register sub circuit of the Nth stage, and a first gate of a first transistor in the shift register sub circuit of the N+1th stage receives the second clock signal, and a second drain of a second transistor in the shift register sub circuit of the N+1th stage receives a third clock signal, and the third gate of the third transistor of the shift register sub circuit of the N+1th stage receives the same clock signal of the first gate of the first transistor of the shift register sub circuit of the N+1th stage; a first gate of a first transistor in the shift register sub circuit of the N+2th stage receives the third clock signal, and a second drain of a second transistor of the shift register sub circuit of the N+2th stage receives the first clock signal, and the third gate of the third transistor of the shift register sub circuit of the N+2th stage receives the same clock signal of the first gate of the first transistor of the shift register sub circuit of the N+1th stage, wherein the third clock signal is a square wave signal, and a high voltage level of the third clock signal and the high voltage level of the first clock signal do not coincide, and the high voltage level of the third clock signal and the high voltage level of the second clock signal do not coincide, and the duty ratio of the third clock signal is smaller than 1.

5. The shift register circuit according to claim 3, wherein the shift register circuit further comprises a shift register sub circuit of a N+1th stage, a shift register sub circuit of a N+2th stage and a shift register sub circuit of a N+3th stage, and the shift register sub circuit of the N+1th stage, the shift register sub circuit of the N+2th stage and the shift register sub circuit of the N+3th stage comprise the same elements of the shift register sub circuit of the Nth stage, and a first gate of a first transistor in the shift register sub circuit of the N+1th stage receives the second clock signal, and a second drain of a second transistor in the shift register sub circuit of the N+1th stage receives a third clock signal, and the third gate of the third transistor of the shift register sub circuit of the N+1th stage receives the same clock signal of the first gate of the first transistor of the shift register sub circuit of the N+1th stage; a first gate of a first transistor in the shift register sub circuit of the N+2th stage receives the third clock signal, and a second drain of a second transistor of the shift register sub circuit of the N+2th stage receives a fourth clock signal, and the third gate of the third transistor of the shift register sub circuit of the N+2th stage receives the same clock signal of the first gate of the first transistor of the shift register sub circuit of the N+1th stage; a first gate of a first transistor in the shift register sub circuit of the N+3th stage receives the fourth clock signal, and a second drain of a second transistor in the shift register sub circuit of the N+3th stage receives the first clock signal, and the third gate of the third transistor in the shift register sub circuit of the N+3th stage receives the same clock signal of the first gate of a first transistor of the shift register sub circuit of the N+3th stage, wherein the third clock signal and the fourth clock signal are square wave signals, and a high voltage level of the third clock signal and a high voltage level of the fourth clock signal do not coincide, and the high voltage level of the third clock signal, the high voltage level of the fourth clock signal and the high voltage level of the first clock signal, the high voltage level of the second clock signal do not coincide, and the duty ratio of the third clock signal is smaller than 1, and the duty ratio of the fourth clock signal is smaller than 1.

6. The shift register circuit according to claim 5, wherein all the duty ratio of the first clock signal, the duty ratio of the second clock signal, the duty ratio of the third clock signal and the duty ratio of the fourth clock signal are 1/3.

7. The shift register circuit according to claim 1, wherein as N is equal to one, the control signal input end of the first stage receives a shift register activation signal, wherein the shift register activation signal is employed to control an activation of the first transistor of the shift register sub circuit of the first stage, wherein the shift register activation signal is a high voltage level signal, of which a lasting period is a first predetermined period.

8. The shift register circuit according to claim 1, wherein the buffer comprises a first inverter and a second inverter sequentially coupled in series, and an input end of the first inverter is coupled to the second source, and an output end of the second inverter is coupled to the signal output end of the Nth stage.

9. The shift register circuit according to claim 8, wherein the buffer further comprises a third inverter, and an input end of the third inverter is electrically coupled to a node between the first inverter and the second inverter, and an output end of the third inverter is electrically coupled to a stage transfer node, and a signal outputted from the output end of the third inverter is transmitted to the shift register sub circuit of the next stage via the stage transfer node.

10. The shift register circuit according to claim 9, wherein the first inverter comprises a first main transistor (T51), a second main transistor (T52), a third main transistor (T53), a fourth main transistor (T54), a first auxiliary transistor (T61), a second auxiliary transistor (T62), a third auxiliary transistor (T63) and a fourth auxiliary transistor (T64); the first main transistor (T51), the second main transistor (T52), the third main transistor (T53), the fourth main transistor (T54), the first auxiliary transistor (T61), the second auxiliary transistor (T62), the third auxiliary transistor (T63) and the fourth auxiliary transistor (T64) respectively comprises a gate, a source and a drain, and both the gate and the source of the first main transistor (T51) are coupled to a high voltage level signal end for receiving a high voltage level signal, and the drain of the first main transistor (T51) is electrically coupled to the gate of the second main transistor (T52), and the source of the second main transistor (T52) is electrically coupled to the high voltage level signal end, and the drain of the second main transistor (T52) is electrically coupled to an output end of the first inverter, and the gate of the third main transistor (T53) is electrically coupled to the input end of the first inverter, and the source of the third main transistor (T53) is electrically coupled to the drain of the first main transistor (T51), and the drain of the third main transistor (T53) is electrically coupled to the drain of the fourth main transistor (T54), and the gate of the fourth main transistor (T54) is electrically coupled to the input end of the first inverter, and the source of the fourth main transistor (T54) is electrically coupled to the output end of the first inverter, and both the gate and the source of the first auxiliary transistor (T61) are coupled to the high voltage level signal end for receiving a high voltage level signal, and the drain of the first auxiliary transistor (T61) is electrically coupled to the gate of the second auxiliary transistor (T62), and the source of the second auxiliary transistor (T62) is electrically coupled to the high voltage level signal end, and the drain of the second auxiliary transistor (T62) is electrically coupled to the drain of the fourth main transistor (T54), and the gate of the third auxiliary transistor (T63) is electrically coupled to the input end of the first inverter, and the source of the third auxiliary transistor (T63) is electrically coupled to the drain of the first auxiliary transistor (T61), and the drain of the third auxiliary transistor (T63) is electrically coupled to a low voltage level signal end (VSS), and the gate of the fourth auxiliary transistor (T64) is electrically coupled to the input end of the first inverter, and the source of the fourth auxiliary transistor (T64) is electrically coupled to the drain of the second auxiliary transistor (T62), and the drain of the fourth auxiliary transistor (T64) is electrically coupled to the low voltage level signal end.

11. The shift register circuit according to claim 10, wherein the second inverter comprises a first main transistor (T71), a second main transistor (T72), a third main transistor (T73), a fourth main transistor (T74), a first auxiliary transistor (T81), a second auxiliary transistor (T82), a third auxiliary transistor (T83) and a fourth auxiliary transistor (T84); the first main transistor (T71), the second main transistor (T72), the third main transistor (T73), the fourth main transistor (T74), the first auxiliary transistor (T81), the second auxiliary transistor (T82), the third auxiliary transistor (T83) and the fourth auxiliary transistor (T84) respectively comprises a gate, a source and a drain, and both the gate and the source of the first main transistor (T71) are coupled to the high voltage level signal end for receiving a high voltage level signal, and the drain of the first main transistor (T71) is electrically coupled to the gate of the second main transistor (T72), and the source of the second main transistor (T72) is electrically coupled to the high voltage level signal end, and the drain of the second main transistor (T72) is electrically coupled to an output end 132 (N) of the second inverter, and the gate of the third main transistor (T73) is electrically coupled to the output end of the first inverter, and the source of the third main transistor (T73) is electrically coupled to the drain of the first main transistor (T71), and the drain of the third main transistor (T73) is electrically coupled to the drain of the fourth main transistor (T74), and the gate of the fourth main transistor (T74) is electrically coupled to the input end of the first inverter, and the source of the fourth main transistor (T74) is electrically coupled to the output end of the second inverter, and the drain of the fourth main transistor (T74) is electrically coupled to source of the fourth auxiliary transistor (T84), and the gate and the source of the first auxiliary transistor (T81) are coupled to the high voltage level signal end for receiving a high voltage level signal, and the drain of the first auxiliary transistor (T81) is electrically coupled to the gate of the second auxiliary transistor (T82), and the source of the second auxiliary transistor (T82) is electrically coupled to the high voltage level signal end, and the drain of the second auxiliary transistor (T82) is electrically coupled to the source of the fourth main transistor (T84), and the gate of the third auxiliary transistor (T83) is electrically coupled to the output end of the first inverter, and the source of the third auxiliary transistor (T83) is electrically coupled to the drain of the first auxiliary transistor (T81), and the drain of the third auxiliary transistor (T83) is electrically coupled to the low voltage level signal end, and the gate of the fourth auxiliary transistor (T84) is electrically coupled to the output end of the first inverter, and the source of the fourth auxiliary transistor (T84) is electrically coupled to the drain of the second auxiliary transistor (T82), and the drain of the fourth auxiliary transistor (T84) is electrically coupled to the low voltage level signal end.

12. The shift register circuit according to claim 11, wherein the third inverter comprises a first main transistor (T31), a second main transistor (T32), a third main transistor (T33), a fourth main transistor (T34), a first auxiliary transistor (T41), a second auxiliary transistor (T42), a third auxiliary transistor (T43) and a fourth auxiliary transistor (T44); the first main transistor (T31), the second main transistor (T32), the third main transistor (T33), the fourth main transistor (T34), the first auxiliary transistor (T41), the second auxiliary transistor (T42), the third auxiliary transistor (T43) and the fourth auxiliary transistor (T44) respectively comprises a gate, a source and a drain, and both the gate and the source of the first main transistor (T31) are coupled to a high voltage level signal end for receiving a high voltage level signal, and the drain of the first main transistor (T31) is electrically coupled to the gate of the second main transistor (T32), and the source of the second main transistor (T32) is electrically coupled to the high voltage level signal end, and the drain of the second main transistor (T32) is electrically coupled to the stage transfer node, and the gate of the third main transistor (T33) is electrically coupled to the output end of the first inverter, and the source of the third main transistor (T33) is electrically coupled to the drain of the first main transistor (T31), and the drain of the third main transistor (T33) is electrically coupled to the drain of the fourth main transistor (T34), and the gate of the fourth main transistor (T34) is electrically coupled to the output end of the first inverter, and the source of the fourth main transistor (T34) is electrically coupled to the stage transfer node, and the drain of the fourth main transistor (T34) is electrically coupled to the source of the fourth auxiliary transistor (T44), and both the gate and the source of the first auxiliary transistor (T41) are coupled to the high voltage level signal end for receiving a high voltage level signal, and the drain of the first auxiliary transistor (T41) is electrically coupled to the gate of the second auxiliary transistor (T42), and the source of the second auxiliary transistor (T42) is electrically coupled to the high voltage level signal end, and the drain of the second auxiliary transistor (T42) is electrically coupled to the source of the fourth auxiliary transistor (T44), and the gate of the third auxiliary transistor (T43) is electrically coupled to the output end of the first inverter, and the source of the third auxiliary transistor (T43) is electrically coupled to the drain of the first auxiliary transistor (T41), and the drain of the third auxiliary transistor (T43) is electrically coupled to a low voltage level signal end, and the gate of the fourth auxiliary transistor (T44) is electrically coupled to the output end of the first inverter, and the source of the fourth auxiliary transistor (T44) is electrically coupled to the drain of the second auxiliary transistor (T42), and the drain of the fourth auxiliary transistor (T44) is electrically coupled to the low voltage level signal end.

13. The shift register circuit according to claim 9, wherein the first inverter comprises a second main transistor (T52), a fourth main transistor (T54), a first auxiliary transistor (T61), a second auxiliary transistor (T62), a third auxiliary transistor (T63) and a fourth auxiliary transistor (T64); the second main transistor (T52), the fourth main transistor (T54), the first auxiliary transistor (T61), the second auxiliary transistor (T62), the third auxiliary transistor (T63) and the fourth auxiliary transistor (T64) respectively comprises a gate, a source and a drain, and the gate of the second main transistor (T52) is electrically coupled to the drain of the first auxiliary transistor (T61), and the source of the second main transistor (T52) is electrically coupled to a high voltage level signal end for receiving a high voltage level signal, and the drain of the second main transistor (T52) is electrically coupled to an output end of the first inverter, and the gate of the fourth main transistor (T54) is electrically coupled to the input end of the first inverter, and the source of the fourth main transistor (T54) is electrically coupled to the output end of the first inverter, and the drain of the fourth main transistor (T54) is electrically coupled to the drain of the second auxiliary transistor (T62), and both the gate and the source of the first auxiliary transistor (T61) are coupled to the high voltage level signal end for receiving a high voltage level signal, and the drain of the first auxiliary transistor (T61) is electrically coupled to the gate of the second auxiliary transistor (T62), and the source of the second auxiliary transistor (T62) is electrically coupled to the high voltage level signal end for receiving a high voltage level signal, and the drain of the second auxiliary transistor (T62) is electrically coupled to the source of the fourth auxiliary transistor (T64). the gate of the third auxiliary transistor (T63) is electrically coupled to the input end of the first inverter, and the source of the third auxiliary transistor (T63) is electrically coupled to the drain of the first auxiliary transistor (T61), and the drain of the third auxiliary transistor (T63) is electrically coupled to a low voltage level signal end (VSS1), and the gate of the fourth auxiliary transistor (T64) is electrically coupled to the input end of the first inverter, and the source of the fourth auxiliary transistor (T64) is electrically coupled to the drain of the second auxiliary transistor (T62), and the drain of the fourth auxiliary transistor (T64) is electrically coupled to the low voltage level signal end (VSS1).

14. The shift register circuit according to claim 13, wherein the second inverter comprises a second main transistor (T72), a fourth main transistor (T74), a first auxiliary transistor (T81), a second auxiliary transistor (T82), a third auxiliary transistor (T83) and a fourth auxiliary transistor (T84); the second main transistor (T72), the fourth main transistor (T74), the first auxiliary transistor (T81), the second auxiliary transistor (T82), the third auxiliary transistor (T83) and the fourth auxiliary transistor (T84) respectively comprises a gate, a source and a drain, and the gate of the second main transistor (T72) is electrically coupled to the drain of the first auxiliary transistor (T81), and the source of the second main transistor (T72) is electrically coupled to the high voltage level signal end, and the drain of the second main transistor (T72) is electrically coupled to an output end of the second inverter, and the gate of the fourth main transistor (T74) is electrically coupled to the output end of the first inverter, and the source of the fourth main transistor (T74) is electrically coupled to the output end of the second inverter, and the drain of the fourth main transistor (T74) is electrically coupled to drain of the second auxiliary transistor (T82), and the gate and the source of the first auxiliary transistor (T81) are coupled to the high voltage level signal end, and the drain of the first auxiliary transistor (T81) is electrically coupled to the gate of the second auxiliary transistor (T82), and the source of the second auxiliary transistor (T82) is electrically coupled to the high voltage level signal end, and the drain of the second auxiliary transistor (T82) is electrically coupled to the source of the fourth main transistor (T84), and the gate of the third auxiliary transistor (T83) is electrically coupled to the output end of the first inverter, and the source of the third auxiliary transistor (T83) is electrically coupled to the drain of the first auxiliary transistor (T81), and the drain of the third auxiliary transistor (T83) is electrically coupled to the low voltage level signal end, and the gate of the fourth auxiliary transistor (T84) is electrically coupled to the output end of the first inverter, and the source of the fourth auxiliary transistor (T84) is electrically coupled to the drain of the second auxiliary transistor (T82), and the drain of the fourth auxiliary transistor (T84) is electrically coupled to the low voltage level signal end.

15. The shift register circuit according to claim 14, wherein the third inverter comprises a second main transistor (T32), a fourth main transistor (T34), a first auxiliary transistor (T41), a second auxiliary transistor (T42), a third auxiliary transistor (T43) and a fourth auxiliary transistor (T44); the second main transistor (T32), the fourth main transistor (T34), the first auxiliary transistor (T41), the second auxiliary transistor (T42), the third auxiliary transistor (T43) and the fourth auxiliary transistor (T44) respectively comprises a gate, a source and a drain, and the gate of the second main transistor (T32) is electrically coupled to the drain of the first auxiliary transistor (T41), and the source of the second main transistor (T32) is electrically coupled to the high voltage level signal end, and the drain of the second main transistor (T32) is electrically coupled to the stage transfer node, and the gate of the fourth main transistor (T34) is electrically coupled to the output end of the first inverter, and the source of the fourth main transistor (T34) is electrically coupled to the stage transfer node, and the drain of the fourth main transistor (T34) is electrically coupled to the source of the fourth auxiliary transistor (T44), and both the gate and the source of the first auxiliary transistor (T41) are coupled to the high voltage level signal end, and the drain of the first auxiliary transistor (T41) is electrically coupled to the gate of the second auxiliary transistor (T42), and the source of the second auxiliary transistor (T42) is electrically coupled to the high voltage level signal end, and the drain of the second auxiliary transistor (T42) is electrically coupled to the source of the fourth auxiliary transistor (T44), and the gate of the third auxiliary transistor (T43) is electrically coupled to the output end of the first inverter, and the source of the third auxiliary transistor (T43) is electrically coupled to the drain of the first auxiliary transistor (T41), and the drain of the third auxiliary transistor (T43) is electrically coupled to a low voltage level signal end, and the gate of the fourth auxiliary transistor (T44) is electrically coupled to the output end of the first inverter, and the source of the fourth auxiliary transistor (T44) is electrically coupled to the drain of the second auxiliary transistor (T42), and the drain of the fourth auxiliary transistor (T44) is electrically coupled to the low voltage level signal end.

16. The shift register circuit according to claim 14, wherein the third inverter comprises a second main transistor (T32), a fourth main transistor (T34), a second auxiliary transistor (T42) and a fourth auxiliary transistor (T44); the second main transistor (T32), the fourth main transistor (T34), the second auxiliary transistor (T42) and the fourth auxiliary transistor (T44) respectively comprises a gate, a source and a drain, and the gate of the second main transistor (T32) is electrically coupled to the gate of the second main transistor (T72) in the second inverter, and the source of the second main transistor (T32) is electrically coupled to the high voltage level signal end, and the drain of the second main transistor (T32) is electrically coupled to the stage transfer node, and the gate of the fourth main transistor (T34) is electrically coupled to the output end of the first inverter, and the source of the fourth main transistor (T34) is electrically coupled to the stage transfer node, and the drain of the fourth main transistor (T34) is electrically coupled to the drain of the second auxiliary transistor (T42), the gate of the second auxiliary transistor (T42) is electrically coupled to the gate of the second main transistor (T32), and the source of the second auxiliary transistor (T42) is electrically coupled to the high voltage level signal end, and the drain of the second auxiliary transistor (T42) is electrically coupled to the source of the fourth auxiliary transistor (T44), and the gate of the fourth auxiliary transistor (T44) is electrically coupled to the output end of the first inverter, and the drain of the fourth auxiliary transistor (T44) is electrically coupled to the low voltage level signal end.
